(19) United States
(12) Patent Application Publication
(10) Pub. No.: US 2025/0081469 A1
(43) Pub. Date: Mar. 6, 2025

(54) VERTICAL SEMICONDUCTOR DEVICE

(71) Applicant: SAMSUNG ELECTRONICS CO., LTD., SUWON-SI (KR)

(72) Inventors: KIJOON KIM, SUWON-SI (KR); TAEYOUNG KIM, SUWON-SI (KR); SUHWAN LIM, SUWON-SI (KR)

(21) Appl. No.: 18/812,283

(22) Filed: Aug. 22, 2024

(30) Foreign Application Priority Data
Sep. 4, 2023 (KR) 10-2023-0116893

(51) Int. Cl. H10B 51/20; H01L 21/28; H01L 29/51; H10B 51/10

(52) U.S. Cl. CPC H10B 51/20; H10B 51/10; H10D 64/033; H10D 64/689

(57) ABSTRACT

A vertical semiconductor device includes: a plurality of insulation patterns on a substrate, the plurality of insulation patterns being spaced apart from each other in a vertical direction; a plurality of channel structures being spaced apart from each other in a first direction, each of the plurality of channel structures including interface insulation patterns, and the plurality of channel structures disposed in a first trench extending in the first direction and passing through the insulation patterns in the vertical direction; a ferroelectric structure on an outer surface of each of the plurality channel structures, the ferroelectric structure protruding in a direction toward a gap between some of the insulation patterns in the vertical direction; and a conductive pattern on a sidewall of the ferroelectric structure, the conductive pattern filling the gap in the vertical direction.

### CROSS-REFERENCE TO RELATED APPLICATION

This patent application claims priority under 35 USC § 119 to Korean Patent Application No. 10-2023-0116893 filed on Sep. 4, 2023, in the Korean Intellectual Property Office (KIPO), the disclosure of which is incorporated by reference in its entirety herein.

### TECHNICAL FIELD

Example embodiments of the present inventive concept are directed to a vertical semiconductor device. More particularly, example embodiments of the present inventive concept are directed to a vertical non-volatile memory device in which cells are stacked in a vertical direction.

### DISCUSSION OF RELATED ART

A vertical memory device is a type of memory where memory cells are stacked vertically, rather than arranged horizontally on a substrate. This arrangement allows for a much denser packing of memory cells, which leads to higher capacity and storage density within a smaller footprint compared to planar memory architectures. The memory cells of the vertical memory device may include a ferroelectric material.

Memory cells that include the ferroelectric material offer several benefits. Polarization states may be stable without power, ensuring data is retained when the device is powered off. Switching the polarization states can be achieved rapidly, resulting in faster read/write operations compared to prior memories. Further, ferroelectric materials can endure a high number of read/write cycles, making them suitable for applications requiring high reliability and longevity.

While ferroelectric vertical memory devices offer significant benefits in terms of integration and density, there are some limitations and challenges that can affect how far integration can be increased. Thus, there is a need for new ferroelectric vertical memory devices with higher integration.

### SUMMARY

Example embodiments of the present inventive concept provide a ferroelectric vertical semiconductor device including memory cells stacked in a vertical direction.

According to an example embodiment of the present inventive concept, a vertical semiconductor device includes: a plurality of insulation patterns, a plurality of channel structures, a ferroelectric structure, and a conductive pattern. The plurality of insulation patterns are disposed on a substrate, where the plurality of insulation patterns are spaced apart from each other in a vertical. The plurality of channel structures are spaced apart from each other in a first direction. Each of the plurality of channel structures include interface insulation patterns, and the plurality of channel structures are disposed in a first trench extending in the first direction and pass through the insulation patterns in the vertical direction. The ferroelectric structure is disposed on an outer surface of each of the plurality channel structures, the ferroelectric structure protruding in a direction towards a gap between some of the insulation patterns in the vertical direction. The conductive pattern is disposed on a sidewall of the ferroelectric structure, where the conductive pattern fills the gap in the vertical direction.

According to an example embodiment of the present inventive concept, a vertical semiconductor device includes: a lower insulating interlayer and a common source plate being sequentially stacked on a substrate; a plurality of insulation patterns disposed on the common source plate, and spaced apart from each other in a vertical direction; a plurality channel structures disposed in a first trench and spaced apart from each other in a first direction, each of the plurality channel structures including interface insulation patterns disposed on each of first and second sidewalls of the first trench, and a channel disposed on the interface insulation patterns and the common source plate; a ferroelectric structure disposed on a surface of each of the interface insulation pattern, the ferroelectric structure protruding toward a gap between some of the insulation patterns in the vertical direction; and a conductive pattern disposed on a sidewall of the ferroelectric structure, the conductive pattern filling the gap. A plurality of first trenches extend in the first direction and are arranged in a second direction different from the first direction, and the plurality of first trenches pass through the insulation patterns in the vertical direction.

According to an example embodiment of the present inventive concept, a vertical semiconductor device includes: a channel disposed on a substrate, the channel including a first vertical extension, a horizontal extension, and a second vertical extension, and having a U-shape; interface insulation patterns disposed on an outer surface of the first vertical extension of the channel and the outer surface of the second vertical extension of the channel, respectively; ferroelectric structures stacked on a surface of each of the interface insulation pattern, where the ferroelectric structures are spaced apart from each other in a vertical direction; and a conductive pattern is disposed on a sidewall of each of the ferroelectric structures.

In example embodiments, the memory cells may be implemented on the first sidewall and the second sidewall of the channel, respectively, so that an integration of the vertical semiconductor device may be increased. Additionally, the memory cells may include the ferroelectric structure, so that the memory cells may have excellent operating characteristics.

### BRIEF DESCRIPTION OF THE DRAWINGS

The above and other features of the present inventive concept will become more apparent by describing in detail example embodiments thereof, with reference to the accompanying drawings, in which:

FIG. 1 is a plan view illustrating a vertical semiconductor device in accordance with an example embodiment of the present inventive concept;

FIG. 2 is a perspective view of a vertical semiconductor device in accordance with an example embodiment of the present inventive concept;

FIG. 3 is an enlarged cross-sectional view of a memory cell of a vertical semiconductor in accordance with an example embodiment of the present inventive concept;

FIG. 4 is a perspective view of a vertical semiconductor device in accordance with an example embodiment of the present inventive concept;

FIG. 5 is a perspective view of a vertical semiconductor device in accordance with an example embodiment of the present inventive concept;

FIG. 6 is a perspective view of a vertical semiconductor device in accordance with an example embodiment of the present inventive concept;

FIG. 7 is a perspective view of a vertical semiconductor device in accordance with an example embodiment of the present inventive concept;

FIG. 8 is a plan view illustrating a vertical semiconductor device in accordance with an example embodiment of the present inventive concept;

FIGS. 9 to 31 are perspective views, cross-sectional views, and an enlarged cross-sectional view illustrating a method for manufacturing a vertical semiconductor device in accordance with an example embodiment of the present inventive concept;

FIG. 32 is a perspective view illustrating a vertical semiconductor device in accordance with an example embodiment of the present inventive concept;

FIG. 33 is an enlarged cross-sectional view of a memory cell of a vertical semiconductor device in accordance with an example embodiment of the present inventive concept;

FIG. 34 is an enlarged cross-sectional view of a memory cell of a vertical semiconductor device in accordance with an example embodiment of the present inventive concept;

FIG. 35 is an enlarged cross-sectional view of a memory cell of a vertical semiconductor device in accordance with an example embodiment of the present inventive concept;

FIG. 36 is a perspective view illustrating a vertical semiconductor device in accordance with an example embodiment of the present inventive concept;

FIG. 37 is an enlarged cross-sectional view of a memory cell of a vertical semiconductor device in accordance with an example embodiment of the present inventive concept;

FIG. 38 is an enlarged cross-sectional view of a memory cell of a vertical semiconductor device in accordance with an example embodiment of the present inventive concept;

FIG. 39 is an enlarged cross-sectional view of a memory cell of a vertical semiconductor device in accordance with an example embodiment of the present inventive concept;

FIG. 40 is a perspective view illustrating a vertical semiconductor device in accordance with an example embodiment of the present inventive concept;

FIG. 41 is an enlarged cross-sectional view of a memory cell of a vertical semiconductor device in accordance with an example embodiment of the present inventive concept;

FIG. 42 is an enlarged cross-sectional view of a memory cell of a vertical semiconductor device in accordance with an example embodiment of the present inventive concept; and

FIG. 43 is an enlarged cross-sectional view of a memory cell of a vertical semiconductor device in accordance with an example embodiment of the present inventive concept.

### DETAILED DESCRIPTION

Various example embodiments of the present inventive concept will be described in detail with reference to the accompanying drawings. The present disclosure may, however, be embodied in many different forms and should not be construed as limited to the embodiments set forth herein. Like reference numerals refer to like elements throughout this application.

Hereinafter, in an embodiment, a direction parallel to a surface of a substrate is referred to as a first direction, a direction parallel to the surface of the substrate and vertically crossing the first direction is referred to as a second direction, and a direction vertical to the surface of the substrate is referred to as a vertical direction.

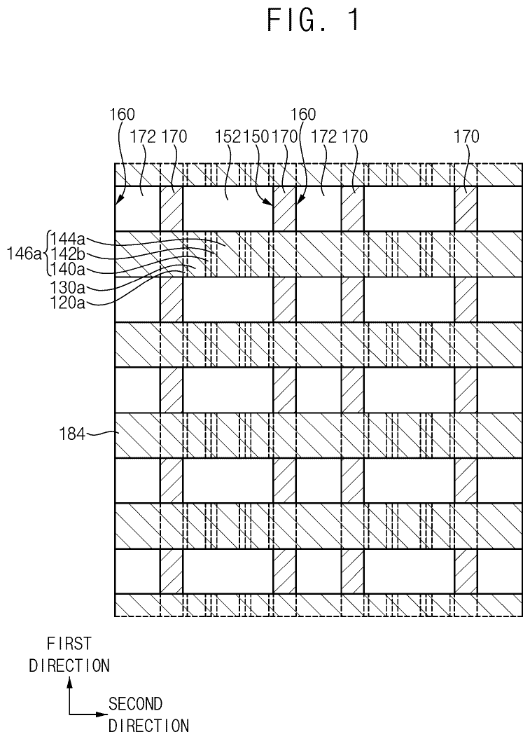

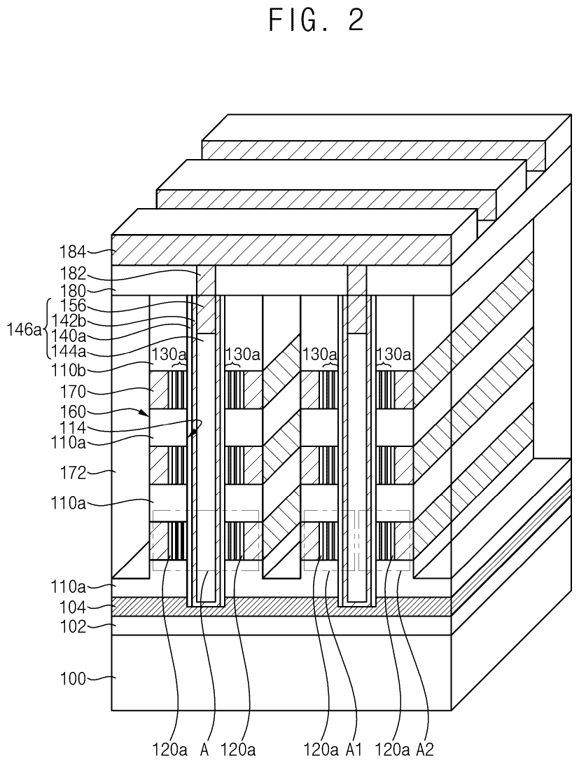

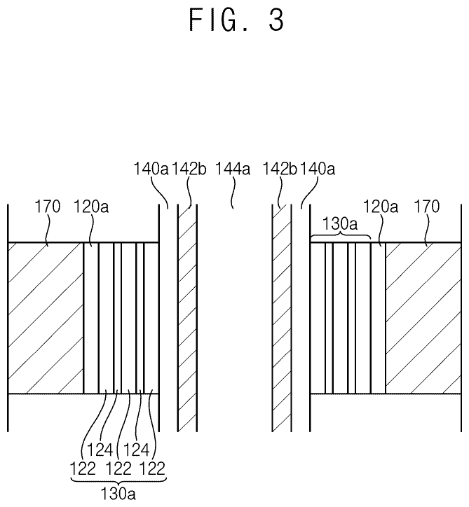

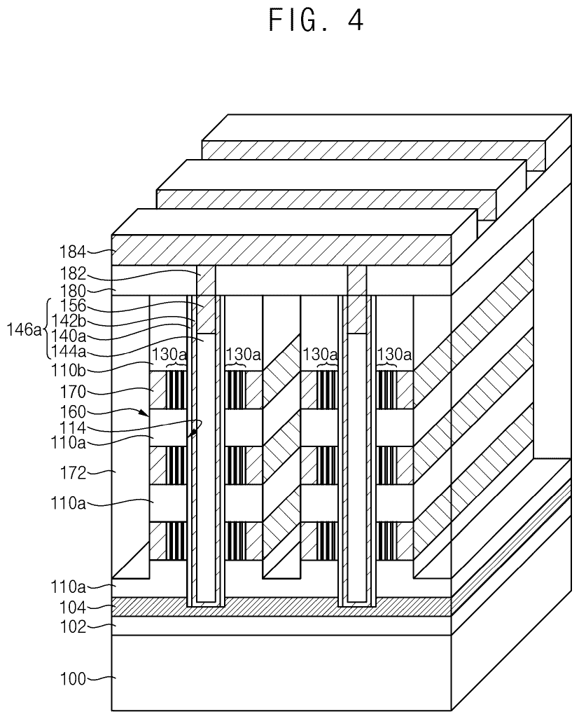

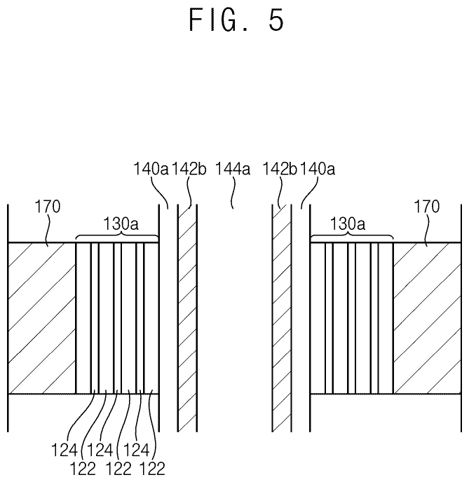

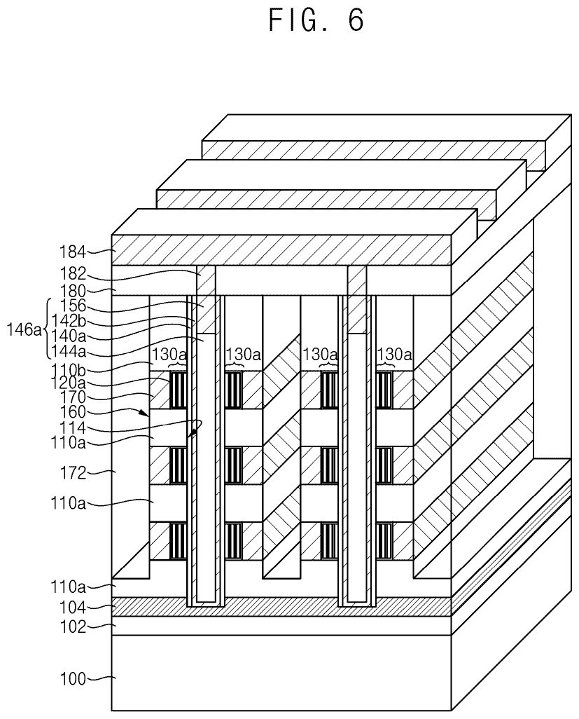

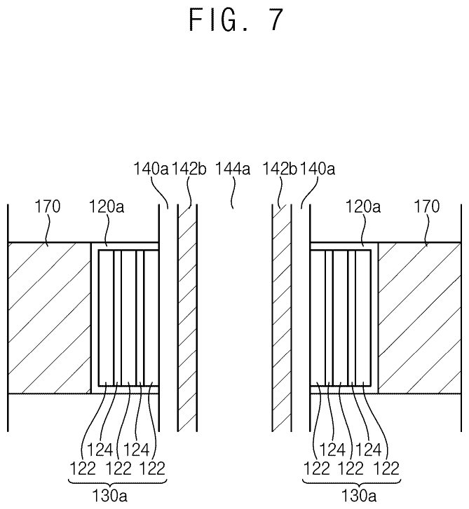

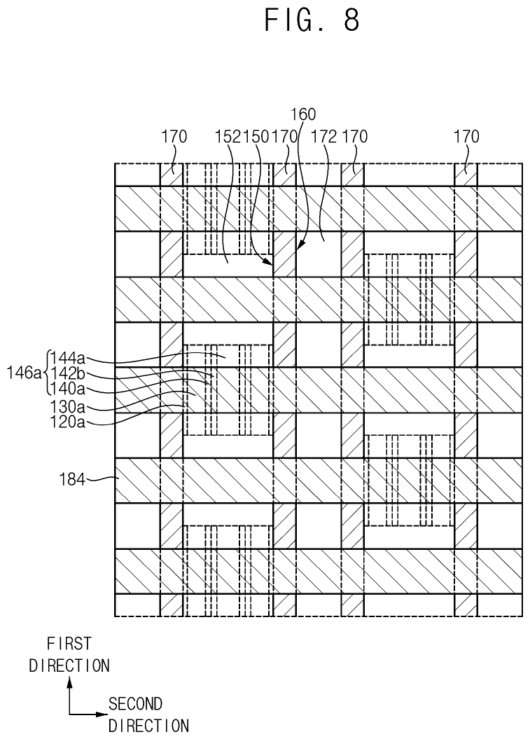

FIG. 1 is a plan view illustrating a vertical semiconductor device in accordance with an example embodiment of the present inventive concept. FIG. 2 is a perspective view of a vertical semiconductor device in accordance with an example embodiment of the present inventive concept. FIG. 3 is an enlarged cross-sectional view of a memory cell of a vertical semiconductor in accordance with an example embodiment of the present inventive concept. FIG. 4 is a perspective view of a vertical semiconductor device in accordance with an example embodiment of the present inventive concept. FIG. 5 is a perspective view of a vertical semiconductor device in accordance with an example embodiment of the present inventive concept. FIG. 6 is a perspective view of a vertical semiconductor device in accordance with an example embodiment of the present inventive concept. FIG. 7 is a perspective view of a vertical semiconductor device in accordance with an example embodiment of the present inventive concept. FIG. 8 is a plan view illustrating a vertical semiconductor device in accordance with an example embodiment of the present inventive concept.

FIG. 3 is an enlarged view of portion A of FIG. 2.

Referring to FIGS. 1 to 3, the vertical semiconductor device is formed on a substrate 100. The substrate 100 may include a semiconductor material such as silicon, germanium, or silicon-germanium, or a group III-V compound such as GaP, GaAs, or GaSb. In some example embodiments, the substrate 100 may be a silicon-on-insulator (SOI) substrate or a germanium-on-insulator (GOI) substrate.

A lower circuit pattern may be formed on the substrate 100, and a lower insulating interlayer 102 may cover the lower circuit pattern. The lower circuit pattern may include, e.g., at least one transistor and at least one wiring. In example embodiments, the lower circuit pattern may serve as peripheral circuits of the vertical semiconductor device.

A common source plate (CSP) 104 may be disposed on the lower insulating interlayer 102. The common source plate 104 may include a semiconductor doped with impurities, a metal, a conductive metal nitride, or a metal silicide. In example embodiments, an upper portion of the common source plate 104 includes a semiconductor material doped with impurities. For example, the common source plate 104 may include polysilicon doped with n-type impurities.

Insulation patterns 110a and 110b being spaced apart from each other in the vertical direction may be on the common source plate 104. Each of the insulation patterns 110a and 110b may extend in the first direction.

In an embodiment, a first trench 114 passes through the insulation patterns 110a and 110b in the vertical direction, and the first trench 114 may extend in the first direction.

In an embodiment, a channel structure 146a is disposed in the first trench 114. In an embodiment, the channel structure 146a passes through the insulation patterns 110a and 110b, and the channel structure 146a extends in the vertical direction into the common source plate 104. The channel structure 146a may have a pillar shape. In an embodiment, a plurality of channel structures 146a are spaced apart from each other in the first direction.

In an example embodiment, the channel structures 146a disposed in the first trenches 114 adjacent in the second direction are arranged to be aligned in the second direction.

However, in some example embodiments, the channel structures 146a disposed in the first trenches 114 adjacent in the second direction are not aligned in the second direction. The channel structures 146a disposed in the first trenches 114 adjacent in the second direction may be arranged in a zigzag manner. An arrangement of the channel structures 146a disposed in the first trenches 114 may vary depending on process architectures.

In an embodiment, each of the channel structures 146a include a channel 142b, interface insulation patterns 140a, a first filling insulation pattern 144a, and a capping conductive pattern 156.

The interface insulation patterns 140a may be formed on a first sidewall and a second sidewall facing each other in the second direction in the first trench 114, respectively. Each of the interface insulation patterns 140a may serve as an interface layer directly contacting the channel 142b.

The channel 142b may be conformally formed on surfaces of the interface insulation patterns 140a and an upper surface of the common source plate 104. For example, the channel 142b may be formed to fit closely and match contours of the interface insulation patterns 140a and an upper surface of the common source plate 104. The channel 142b may include a first vertical extension portion, a horizontal extension portion, and a second vertical extension portion. The interface insulation patterns 140a may be formed on outer surfaces of the first and second vertical extension portions of the channel 142b, respectively. The horizontal extension portion may be formed on the upper surface of the common source plate 104. Accordingly, the channel 142b may have a U-shape.

In an embodiment, the first filling insulation pattern 144a is on an inner surface of the channel 142b to fill the first trench 114. The first filling insulation pattern 144a may fill all or most of the first trench 114. The capping conductive pattern 156 may be disposed on the first filling insulation pattern 144a, and may contact an upper portion of the channel 142b.

The interface insulation pattern 140a may include, e.g., silicon oxide, or a metal oxide having a high dielectric constant. In an embodiment, the interface insulation pattern 140a is entirely silicon oxide, or entirely a metal oxide having a high dielectric constant. In example embodiments, the channel 142b may include polysilicon. In some example embodiments, the channel 142b may include an oxide semiconductor layer. The first filling insulation pattern 144a may include, e.g., silicon oxide or silicon nitride. The capping conductive pattern 156 may include, e.g., polysilicon. In an embodiment, the channel 142b is entirely polysilicon or entirely an oxide semiconductor layer. In an embodiment, the first filling insulation pattern 144a is entirely silicon oxide or entirely silicon nitride. In an embodiment, the capping conductive pattern 156 is entirely polysilicon.

The insulation patterns 110a and 110b may laterally protrude from a surface of each of the interface insulation patterns 140a of the channel structure 146a.

A second filling insulation pattern 152 may be disposed between the channel structures 146a being spaced apart from each other in the first direction in the first trench 114. The second filling insulation pattern 152 may include, e.g., silicon oxide or silicon nitride. In an embodiment, the second filling insulation pattern 152 is entirely silicon oxide or entirely silicon nitride. The second filling insulation pattern 152 may be disposed in the first opening 150 extending from an uppermost insulation pattern 110b into the common source plate 104 in the vertical direction. The second filling insulation pattern 152 may have an isolated shape. For example, the second filling insulation pattern 152 may have a shape that is distinct and separate from other layers or components.

A gap or recess may be disposed between neighboring insulation patterns 110a and 110b in the vertical direction. The recess may be defined by the neighboring insulation patterns 110a and 110b in the vertical direction and the channel structure 146a. The recess may extend in the first direction.

In an embodiment, a ferroelectric structure 130a is disposed in the recess, and may contact each of the interface insulation patterns 140a. The ferroelectric structure 130a may include at least two ferroelectric layers 122.

In an example embodiment, a first oxide layer pattern 120a is disposed on a surface of the ferroelectric structure 130a. For example, the first oxide layer pattern 120a may be disposed on one of the ferroelectric layers 122.

The ferroelectric structure 130a may be disposed on an outer surface of each of the channel structures 146, and may laterally protrude toward the gap between neighboring insulation patterns 110a and 110b in the vertical direction from the outer surface of each of the channel structures 146. That is, the ferroelectric structure 130a may laterally protrude from the surface of each of the interface insulation patterns 140a included in the channel structure 146a. A plurality of the ferroelectric structures 130a being spaced apart from each other in the vertical direction may be disposed on a corresponding one of the interface insulation patterns 140a.

As shown in FIG. 3, the ferroelectric structure 130a may include ferroelectric layers 122 and conductive material layers 124 alternately stacked. For example, a conductive material layer 124 may be disposed between two of the ferroelectric layers 122.

In example embodiments, the ferroelectric layers 122 and the conductive material layers 124 may be alternately and repeatedly stacked in a lateral direction from the surface of the interface insulation pattern 140a exposed by the recess. Each of the ferroelectric layers 122 and the conductive material layers 124 may be arranged in the vertical direction respect to the surface of the substrate 100. Additionally, the first oxide layer pattern 120a may be arranged in the vertical direction respect to the surface of the substrate 100.

In example embodiments, the ferroelectric layer 122 may include a hafnium oxide layer, a zirconium oxide layer, or a hafnium zirconium oxide layer. The ferroelectric layer 122 may have an orthorhombic phase. The ferroelectric layer 122 may include dopants, and the dopants may be, e.g., silicon (Si), zirconium (Zr), aluminum (Al), yttrium (Y), lanthanum (La), carbon (C), nitrogen (N), germanium (Ge), tin (Sn), strontium (Sr), lead (Pb), calcium (Ca), barium (Ba), titanium (Ti), zirconium (Zr), or gadolinium (Gd), etc.

In an example embodiment, the ferroelectric layer 122 includes a ferroelectric material having a perovskite structure. For example, the ferroelectric layer 122 may include Strontium Bismuth Tantalate SrBi2Ta2O9, Bismuth Lanthanum Titanate (Bi,La)4Ti3O12, or Lead Zirconate Titanate (Pb,Zr)TiO3.

The conductive material layer 124 may include, e.g., metal or metal oxide having a thickness as thin as an atomic layer. In example embodiments, a thickness of the conductive material layer 124 may be in range of about 0.1 Angstrom (Å) to about 0.5 Å.

The conductive material layer 124 may include, e.g., titanium or titanium oxide. The conductive material layer 124 may include, e.g., a metallic two-dimensional material. The conductive material layer 124 may be, e.g., a two-dimensional metal dichalcogenide (TMD). In this case, a metal included in the TMD may include, e.g., molybdenum (Mo), tungsten (W)), rhenium (Re), tin (Sn), niobium (Nb), tantalum (Ta), bismuth (Bi) or platinum (Pt), and a chalcogen material included in the TMD may include, e.g., sulfur (S), selenium (Se), or tellurium (Te). The conductive material layer 124 may include, e.g., molybdenum disulfide (MoS2), tungsten diselenide (WSe2), titanium trisulfide (TiS3), gallium selenide (GaSe), Ga2N3, bismuth oxyselenide (BiO2Se), etc. The conductive material layers 124 may be inserted into the ferroelectric structure 130a, so that the ferroelectric layer 122 included in the ferroelectric structure 130a may be induced to have an orthorhombic phase. Therefore, a polarization characteristic of the ferroelectric structure 130a may be increased.

A conductive pattern 170 may be disposed on the first oxide layer pattern 120a to fill the recess. The conductive pattern 170 may extend in the first direction, and the conductive pattern 170 may face the plurality of channel structures 146a arranged in the first direction. The conductive pattern 170 may be a conductor or include a conductive material.

The conductive pattern 170 may serve as a gate electrode. Additionally, the conductive pattern 170 extending in the first direction may serve as a word line.

In example embodiments, the conductive pattern 170 may include polysilicon or a metal. The metal included in the conductive pattern 170 may include, e.g., tungsten.

In an embodiment, the first oxide layer pattern 120a is disposed between the conductive pattern 170 and the ferroelectric structure 130a, and may serve as an interface insulation layer of the conductive pattern 170. In an embodiment, the first oxide layer pattern 120a directly contacts the conductive pattern 170. The first oxide layer pattern 120a may include, e.g., a silicon oxide layer.

In some example embodiments, as shown in FIGS. 4 and 5, the first oxide layer pattern 120a is not formed on the ferroelectric structure 130a. That is, the conductive pattern 170 may directly contact the ferroelectric structure 130a. For example, the first oxide layer pattern 120a may be omitted.

In some example embodiments, as shown in FIGS. 6 and 7, the first oxide layer pattern 120a is conformally formed on the surfaces of the neighboring insulation patterns 110a and 110b and the conductive pattern 170 in the recess. That is, in the cross-sectional view, the first oxide layer pattern 120a may have a “⊏”-shape or a U shape on its side.

A second trench 160 may be disposed between the conductive patterns 170 adjacent in the second direction. The second trench 160 may extend in the first direction. A third filling insulation pattern 172 may be disposed in the second trench 160.

The third filling insulation pattern 172 may extend in the first direction, and may contact the conductive patterns 170 adjacent in the second direction. The third filling insulation pattern 172 may extend in the vertical direction from an uppermost insulation pattern 110b to a lowermost insulation pattern 110a.

In an example embodiment, the first trench 114 has an internal width of a predetermined size. Additionally, a pitch of the first trench 114, which is a sum of the internal width of the first trench 114 and a space between the first trenches 114, may be four times the predetermined size. In an embodiment, the pitch of the first trench 114 is 4 times the predetermined size. In an embodiment, the second trench 160 has an internal width of the predetermined size. Additionally, a space between the first and second trenches 114 and 160 may be the predetermined size. In example embodiments, the predetermined size may be a minimum width or a minimum space that can be formed by a photolithography process. For example, the predetermined size may be about 10 nanometers (nm) to about 50 nm, but is not limited thereto.

In example embodiments, as shown in FIG. 1, when the channel structures 146a are arranged to be aligned in the second direction, the channel structures 146a may have a width of the predetermined size in the first direction. A space in the first direction between the channel structures 146a (that is, a width in the first direction of the second filling insulation pattern) may be the predetermined size.

In some example embodiments, as shown in FIG. 8, when the channel structures 146a are arranged in a zigzag manner in the second direction, the channel structures 146a have a width in the first direction of 2 times the predetermined size. The space in the first direction between the channel structures 146a (that is, the width in the first direction of the second filling insulation pattern) may be 2 times the predetermined size. The channel structures 146a are arranged in a zigzag manner in the second direction may mean that a first column of the channel structures 146a start at a first position and second column of the channel structures 146a start at second other position such as a position lower than the first position.

The channel 142b, and the interface insulation pattern 140a, the ferroelectric structure 130a, the first oxide layer pattern 120a, and the conductive pattern 170 laterally stacked on the sidewall of the channel 142b may serve as one memory cell.

When the channel 142b has a U-shape, the channel 142b may have a first sidewall and a second sidewall facing to other in the second direction. The interface insulation pattern 140a, the ferroelectric structure 130a, the first oxide layer pattern 120a, and the conductive pattern 170 may be stacked on the first sidewall of the channel 142b. The interface insulation pattern 140a, the ferroelectric structure 130a, the first oxide layer pattern 120a, and the conductive pattern 170 may be stacked on the second sidewall of the channel 132b. The interface insulation pattern 140a, the ferroelectric structure 130a, the first oxide layer pattern 120a, and the conductive pattern 170 stacked on the first sidewall of the channel 132b may serve as a first memory cell A1 (refer to FIG. 2). The interface insulation pattern 140a, the ferroelectric structure 130a, the first oxide layer pattern 120a, and the conductive pattern 170 stacked on the second sidewall of the channel 142b may serve as a second memory cell A2 (refer to FIG. 2). Accordingly, the first memory cell A1 may be formed on the first sidewall of the channel 142b, and the second memory cell A2 may be formed on the second sidewall of the channel 142b. The first and second memory cells A1 and B2 may be distinct from each other, and may operate independently.

A first insulating interlayer 180 may be disposed on the uppermost insulation pattern 110b, the channel structure 146a, the second filling insulation pattern 152, and the third filling insulation pattern 172. A contact plug 182 may contact the capping conductive pattern 156 through the first insulating interlayer 180. In an embodiment, the capping conductive pattern 156 extends from a bottom surface of the first insulating interlayer 180 to the first filling insulation pattern 144a.

An upper conductive line 184 extending in the second direction may be disposed on the contact plug 182. The upper conductive line 184 may be electrically connected to the channel 142b included in the channel structure 146a.

The upper conductive line 184 may serve as a bit line structure. In example embodiments, a width of the upper conductive line 184 is the predetermined size. Additionally, a pitch of the upper conductive line 184 may be 2 times the predetermined size.

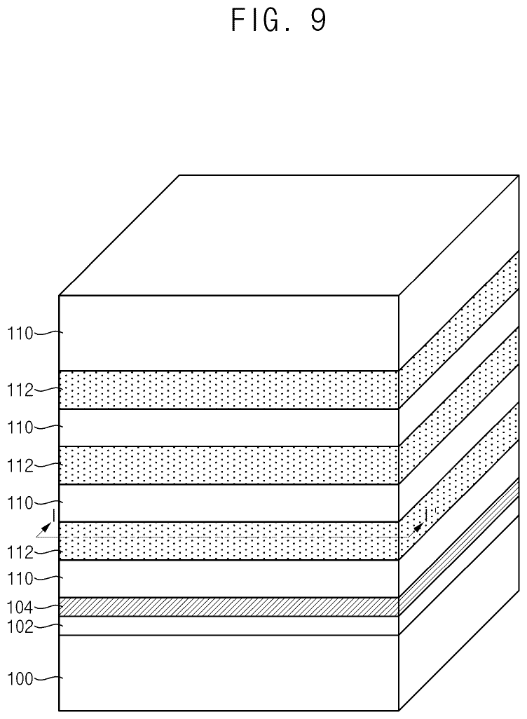

FIGS. 9 to 31 are perspective views, cross-sectional views, and an enlarged cross-sectional view illustrating a method for manufacturing a vertical semiconductor device in accordance with an example embodiment of the present inventive concept.

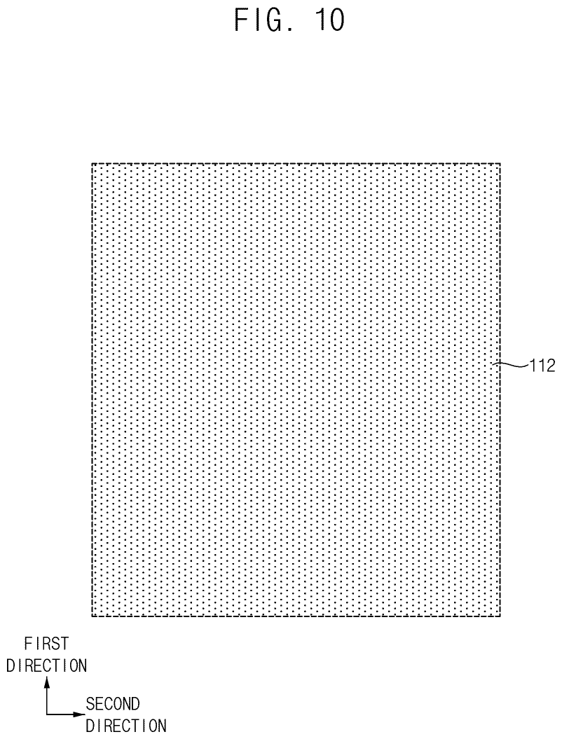

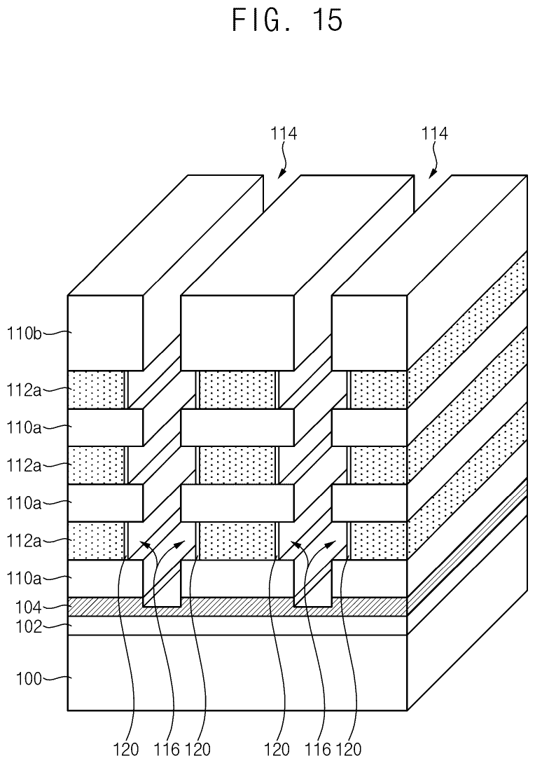

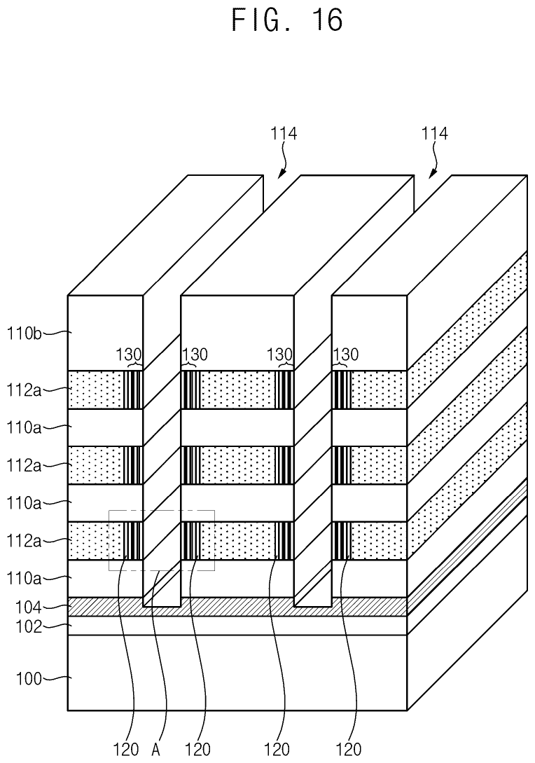

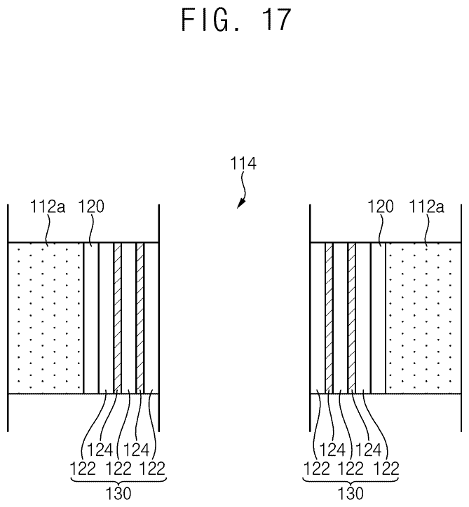

FIGS. 9, 11, 13, 15, 16, 19, 22, 25, 26, 28, 29 and 31 are perspective views. FIGS. FIGS. 10, 12, 14, 18, 20, 21, 23, 24, 27, and 30 are cross-sectional views taken along line I-I′ of FIG. 9. FIG. 17 is an enlarged cross-sectional view of portion A of FIG. 16.

Referring to FIGS. 9 and 10, a lower circuit pattern may be formed on the substrate 100. A lower insulating interlayer 102 may be formed to cover the lower circuit patterns. For example, the lower insulating interlayer 102 may be formed on the substrate 100.

A common source plate 104 is formed on the lower insulating interlayer 102. The common source plate 104 may be formed by forming a common plate electrode layer and patterning the common plate electrode layer. The common plate electrode layer may be formed by, e.g., a chemical vapor deposition process or an atomic layer deposition process.

An insulation layer 110 and a sacrificial layer 112 may be alternately and repeatedly formed on the common source plate 104. The sacrificial layer 112 may include an insulation material having a high etch selectivity with respect to the insulation layer 110. In example embodiments, the insulation layer 110 may include silicon oxide, and the sacrificial layer 112 may include silicon nitride. While FIG. 9 illustrates stacking three insulation layers 110 and three sacrificial layers 112, the number of stacked insulation layers 110 and sacrificial layers 112 is not limited thereto.

An insulation layer 110 may be disposed on upper most portion of a stacked structure in which the insulation layers 110 and sacrificial layers 112 are stacked. In an example embodiment, an uppermost insulation layer 110 is formed to have a thickness greater than a thickness of each of the insulation layers 110 disposed below the uppermost insulation layer 110.

In some example embodiments, processes for forming the lower insulating interlayer 102 and the common source plate 104 are not performed, and the insulation layers and sacrificial layers are formed on the substrate 100. For example, the lower insulating interlayer 102 and the common source plate 104 may be omitted.

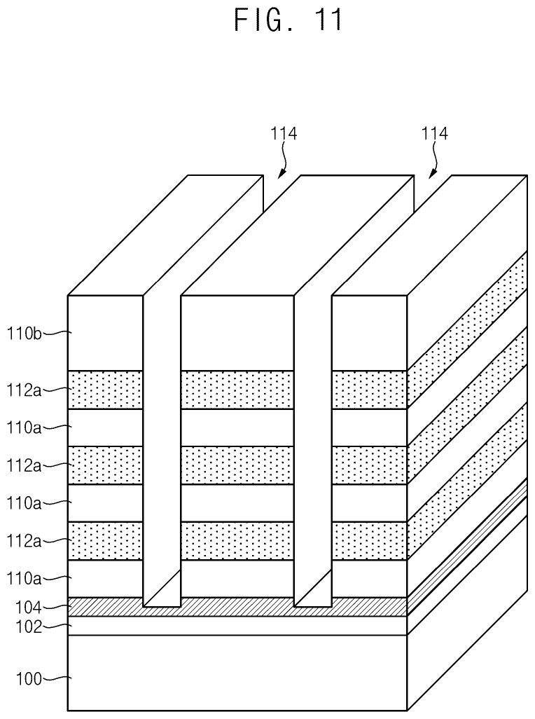

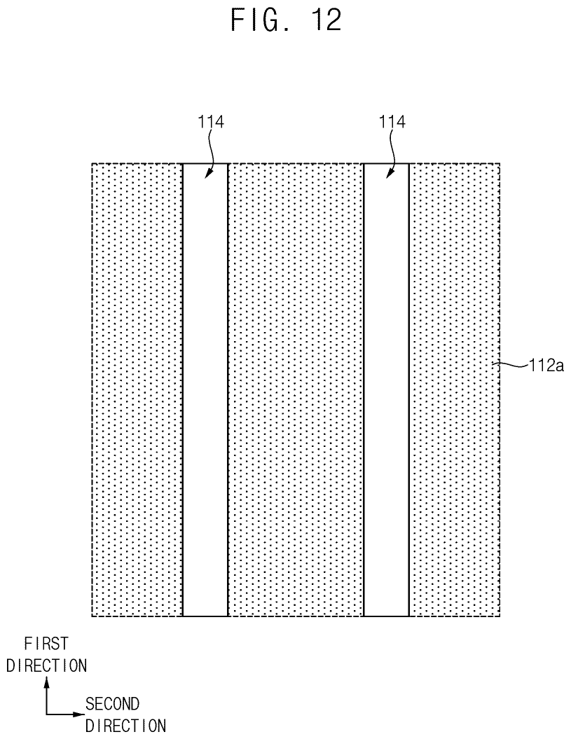

Referring to FIGS. 11 and 12, the stacked structure in which the insulation layers 110 and the sacrificial layers 112 are stacked may be anisotropically etched to form a first trench 114 passing through the stacked structure and exposing an upper portion of the common source plate 104. For example, portions of the insulation layers 110 and the sacrificial layers 112 may be removed to form the first trench 114. The first trench 114 may extend in the first direction. As the first trench 114 is formed, the insulation layer 110 and the sacrificial layer 112 may be transformed into insulation patterns 110a and 110b and sacrificial patterns 112a, respectively.

Sidewalls of the insulation patterns 110a and 110b and the sacrificial pattern 112a may be exposed by sidewalls of the first trench 114. The sidewalls of the insulation patterns 110a and 110b and the sacrificial pattern 112a may correspond to the sidewalls of the first trench 114.

In example embodiments, a plurality of first trenches 114 may be spaced apart from each other in the second direction.

In example embodiments, the first trench 114 has an internal width of the predetermined size. Additionally, a pitch of the first trench 114 may be 4 times the predetermined size.

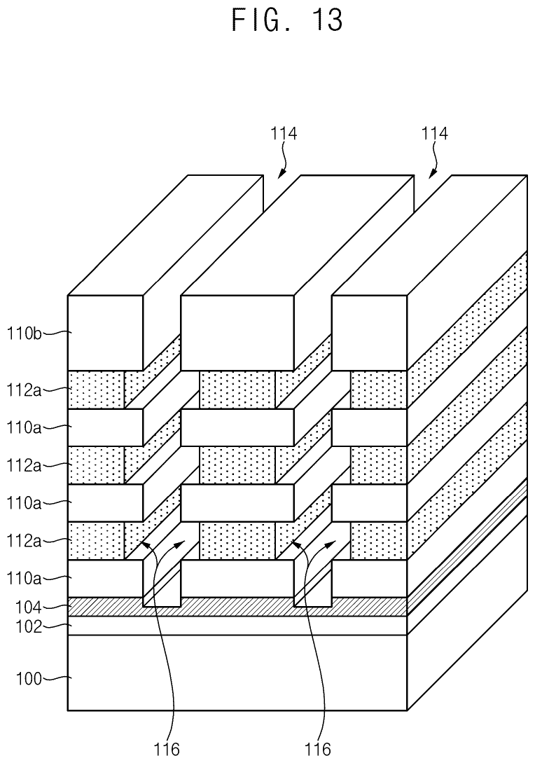

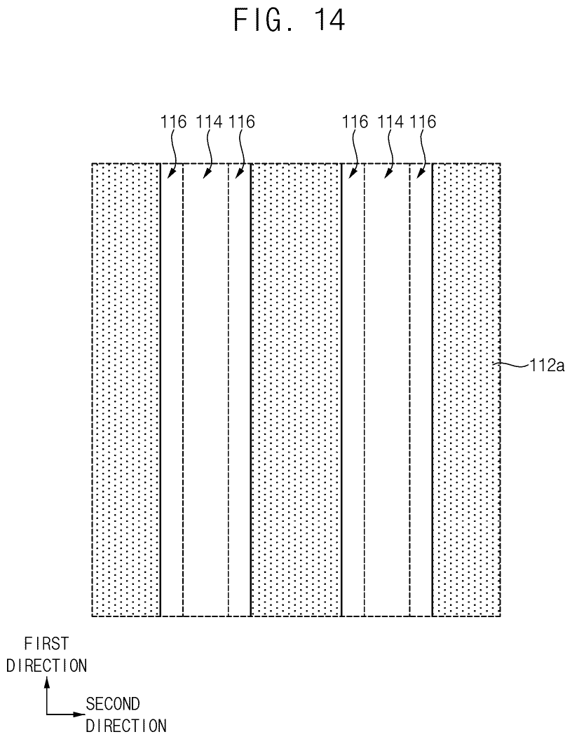

Referring to FIGS. 13 and 14, the sacrificial patterns 112a exposed by the sidewalls of the first trench 114 may be selectively removed to a predetermined thickness to form a first recess 116. The first recess 116 may correspond to a portion where the sacrificial pattern 112a is partially removed.

When the removing process is performed, the insulation patterns 110a and 110b exposed by the sidewalls of the first trench 114 may protrude from the sacrificial pattern 112a exposed by the sidewalls of the first trench 114 in a lateral direction.

The removing process of a portion of the sacrificial pattern 112a may include an isotropic etching process, e.g., a wet etching process.

Referring to FIG. 15, a first oxide layer 120 may be selectively formed on the sidewall of the sacrificial pattern 112a exposed by the first recess 116. The first oxide layer 120 may include, e.g., a silicon oxide layer. The first oxide layer 120 may have a vertically standing shape. For example, the shape of the first oxide layer 120 may be taller than it is wide. The first oxide layer 120 may be arranged in the vertical direction with respect to the surface of the substrate 100. The first oxide layer 120 may serve as a gate electrode interface layer for contacting a conductive pattern subsequently formed. The gate electrode interface layer may directly contact the conductive pattern.

In some example embodiments, the first oxide layer is not formed. In this case, the semiconductor devices shown in FIGS. 4 and 5 may be manufactured by subsequent processes.

In some example embodiments, the first oxide layer 120 is conformally formed on the sidewall of the sacrificial pattern 112a and surfaces of neighboring insulation patterns 110a and 110b exposed by the first recess 116. In this case, before forming an interface insulation layer contacting a channel, the first oxide layer 120 formed on the sidewalls of the insulation patterns 110a and 110b outside of the first recess 116 is selectively removed. Therefore, the semiconductor devices shown in FIGS. 6 and 7 may be manufactured by subsequent processes.

Referring to FIGS. 16, 17, and 18, a preliminary ferroelectric structure 130 is formed on the first oxide layer 120 to fill the first recess 116. In this case, the preliminary ferroelectric structure 130 are not formed on the insulation patterns 110a and 110b corresponding to the sidewalls of the first trench 114.

In example embodiments, the preliminary ferroelectric structure 130 is formed by alternately and repeatedly stacking the ferroelectric layer 122 and the conductive material layer 124.

The ferroelectric layer 122 and the conductive material layer 124 may be formed by a selective deposition process in which layers are selectively formed only on an upper surface of a specific layer. In example embodiments, the ferroelectric layer 122 and the conductive material layer 124 may be selectively formed on the first oxide layer 120. The ferroelectric layer 122 and the conductive material layer 124 may be formed by, e.g., a bottom up deposition process. Accordingly, the ferroelectric layer 122 and the conductive material layer 124 may be deposited only on a surface of the first oxide layer 120 exposed by the sidewall of the first recess 116. However, the ferroelectric layer 122 and the conductive material layer 124 may not be deposited or may be barely deposited on the insulation patterns 110a corresponding to upper and lower surfaces of the first recess 116.

The ferroelectric layer 122 and the conductive material layer 124 may be laterally deposited on the first oxide layer 120 to have a vertically standing shape.

In example embodiments, the ferroelectric layer 122 may include a hafnium oxide layer, a zirconium oxide layer, or a hafnium zirconium oxide layer. The ferroelectric layer may have an orthorhombic phase. The ferroelectric layer 122 may include dopants, and the dopant may be, e.g., silicon (Si), zirconium (Zr), aluminum (Al), yttrium (Y), lanthanum (La), or carbon (C), nitrogen (N), germanium (Ge), tin (Sn), strontium (Sr), lead (Pb), calcium (Ca), barium (Ba), titanium (Ti), zirconium (Zr), gadolinium (Gd), etc.

In some example embodiments, the ferroelectric layer 122 may include a ferroelectric material having a perovskite structure. For example, the ferroelectric layer 122 may include SrBi2Ta2O9, (Bi,La)4Ti3O12, or (Pb,Zr)TiO3.

The conductive material layer 124 may include metal or metal oxide having a thickness as thin as an atomic layer. Each conductive material layer 124 may have a thickness of, e.g., about 0.1 Å to about 0.5 Å.

The conductive material layer 124 may include, e.g., titanium or titanium oxide. For example, the conductive material layer 124 may include a metallic two-dimensional material. The conductive material layer 124 may include, e.g., a two-dimensional metal dichalcogenide (TMD). In this case, a metal included in the TMD may include, e.g., Mo, W, Re, Sn, Nb, Ta, Bi or Pt, and a chalcogen material included in the TMD may include, e.g., S, Se, or Te. The conductive material layer 124 may include, e.g., MoS2, WSe2, TiS3, GaSe, Ga2N3, BiO2Se, etc.

When the conductive material layer 124 is inserted into the preliminary ferroelectric structure 130, the ferroelectric layer 122 may be induced to have an orthorhombic phase. Therefore, a polarization characteristic of the ferroelectric structure 130a may be increased.

Accordingly, the preliminary ferroelectric structure 130 may fill the first recess 116 without voids. The surface of the common source plate 104 may be exposed by the bottom of the first trench 114.

In example embodiments, after performing the above processes, a cleaning process may be further performed to additionally remove portions of the preliminary ferroelectric structure 130 outside of the first recess 116.

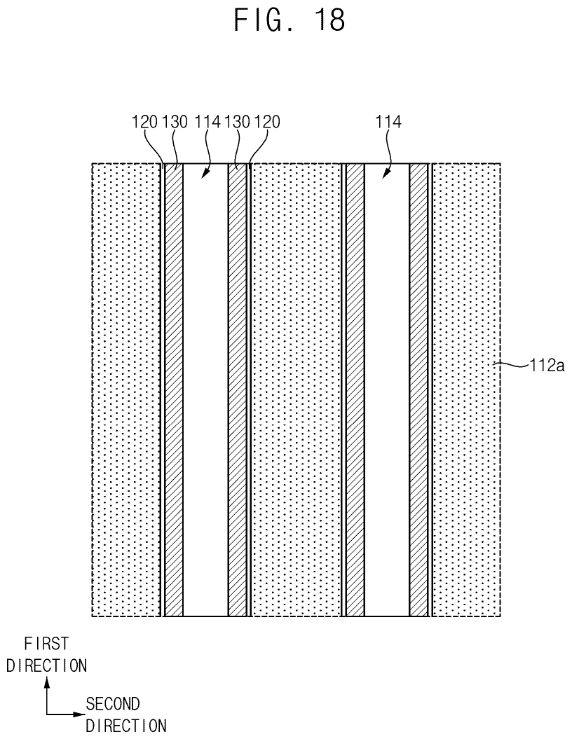

Referring to FIG. 19, an interface insulation layer may be conformally formed on the sidewalls and bottom of the first trench 114 and an upper surface of the uppermost insulation patterns 110b. The interface insulation layer may contact the preliminary ferroelectric structure 130 and the insulation patterns 110b on the sidewalls of the first trench 114. The interface insulation layer may include, e.g., silicon oxide or a metal oxide having a high dielectric constant.

The interface insulation layer may be anisotropically etched to form a preliminary interface insulation pattern 140 on the sidewalls of the first trench 114. In the anisotropic etching process, the interface insulation layer formed on the bottom of the first trench 114 and an upper surface of the uppermost insulation pattern 110b may be removed. Accordingly, the surface of the common source plate 104 may be exposed by the bottom of the first trench 114.

A channel layer 142 may be conformally formed on the preliminary interface insulation pattern 140, the upper surface of the uppermost insulation pattern 110b, and the surface of the common source plate 104.

In example embodiments, the channel layer 142 may include polysilicon. In some example embodiments, the channel layer 142 may include an oxide semiconductor layer.

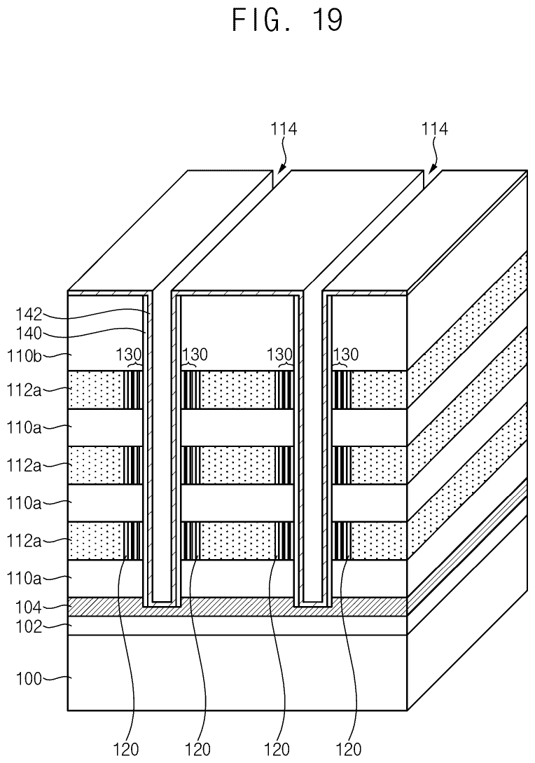

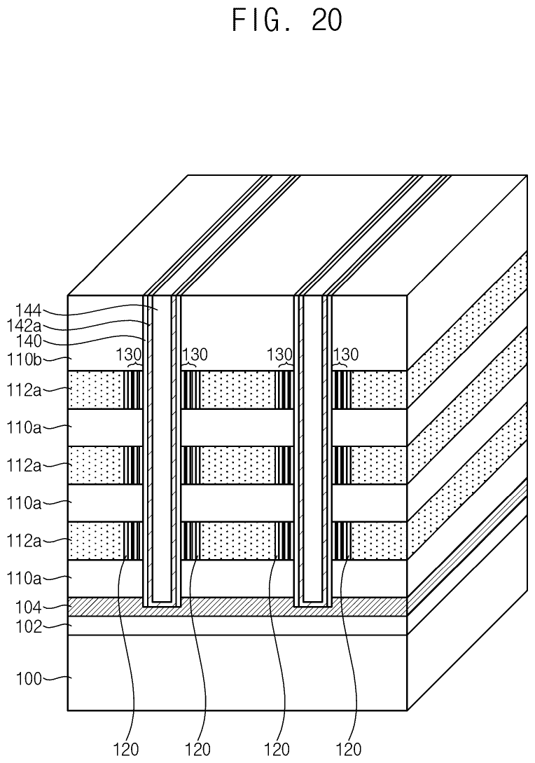

Referring to FIGS. 20 and 21, a first filling insulation layer is formed on the channel layer 142 to fill the first trench 114. The first filling insulation layer and the channel layer 142 may be planarized to expose the upper surface of the uppermost insulation pattern 110b. The planarization process may include a chemical mechanical polishing (CMP) process or an etch-back process.

Accordingly, the channel layer 142 and the first filling insulation layer may be transformed into a preliminary channel 142a and a preliminary first filling insulation pattern 144, respectively. The preliminary first filling insulation pattern 144 may include, e.g., silicon oxide or silicon nitride.

When the above process is performed, the preliminary interface insulation pattern 140, the preliminary channel 142a, and the preliminary first filling insulation pattern 144 may be formed in the first trench 114. The preliminary ferroelectric structure 130 and the first oxide layer 120 may be laterally stacked on the preliminary interface insulation pattern 140.

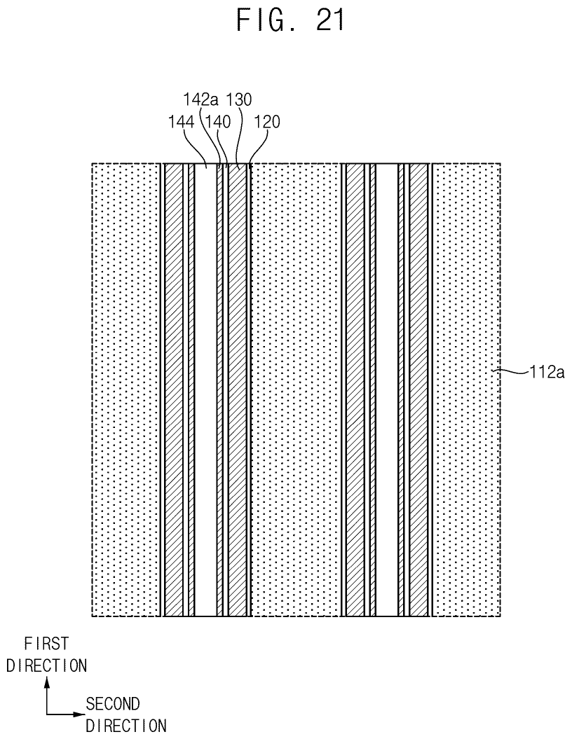

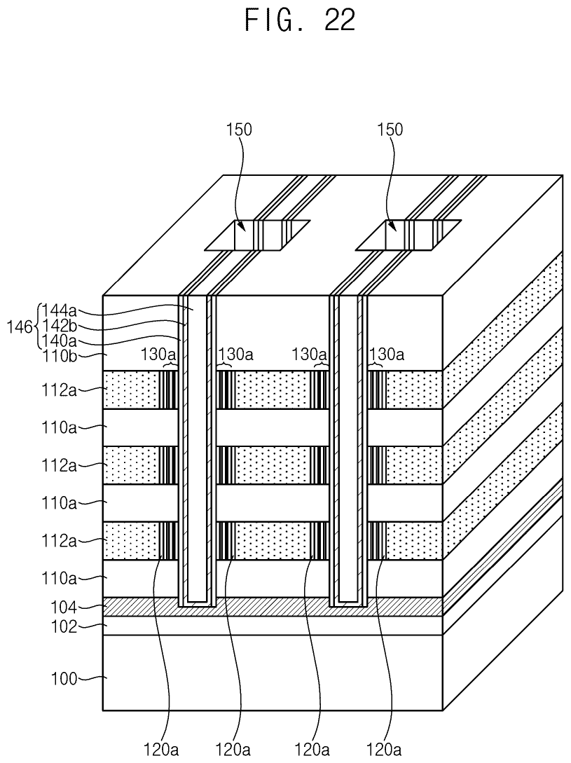

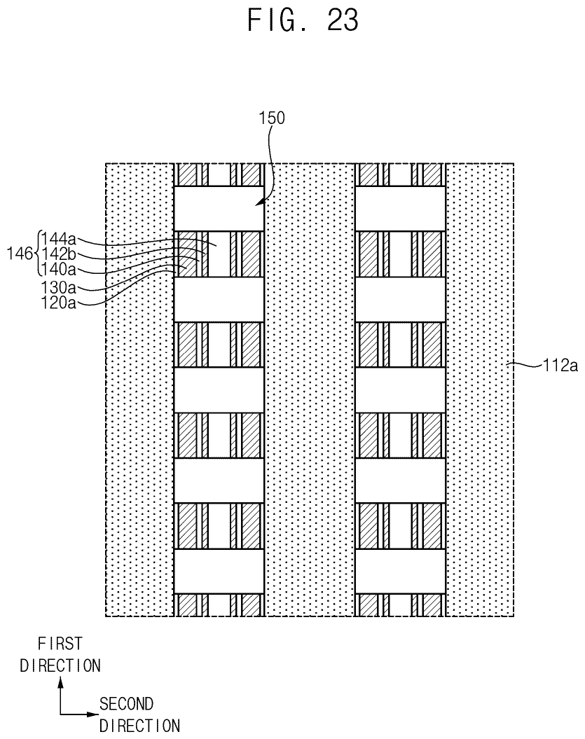

Referring to FIGS. 22 and 23, a preliminary interface insulation pattern 140, a preliminary channel 142a, and a preliminary first filling insulation pattern 144 formed in the first trench 114, and the preliminary ferroelectric structure 130 and the first oxide layer 120 and the insulation patterns 110a and 110b stacked on the sidewalls of the first trench 114 may be anisotropically etched to form first openings 150. For example, portions of the preliminary interface insulation pattern 140, the preliminary channel 142a, the preliminary first filling insulation pattern 144, the preliminary ferroelectric structure 130, the first oxide layer 120 and the insulation patterns 110a and 110b may be removed to form the first openings 150. The first opening 150 may extend from the uppermost insulation pattern 110b to the upper portion of the common source plate 104 in the vertical direction. Therefore, the surface of the common source plate 104 may be exposed by the first opening 150.

The preliminary interface insulation pattern 140, the preliminary channel 142a, and the preliminary first filling insulation pattern 144 formed in the first trench 114, and the preliminary ferroelectric structure 130 and the first oxide layer 120 stacked on the sidewalls of the first trench 114 may be cut by forming the first opening 150. Additionally, the first openings 150 may be overlap the first trench 114, and the first openings 150 being spaced apart from each other in the first direction may be repeatedly arranged in the first trench 114.

In example embodiments, as shown in FIG. 23, the first openings 150 positioned in the first trenches 114 adjacent in the second direction may be arranged to be aligned in the second direction. In this case, the first opening 150 may have, e.g., an internal width in the second direction of the predetermined size and a pitch in the second direction of 2 times the predetermined size.

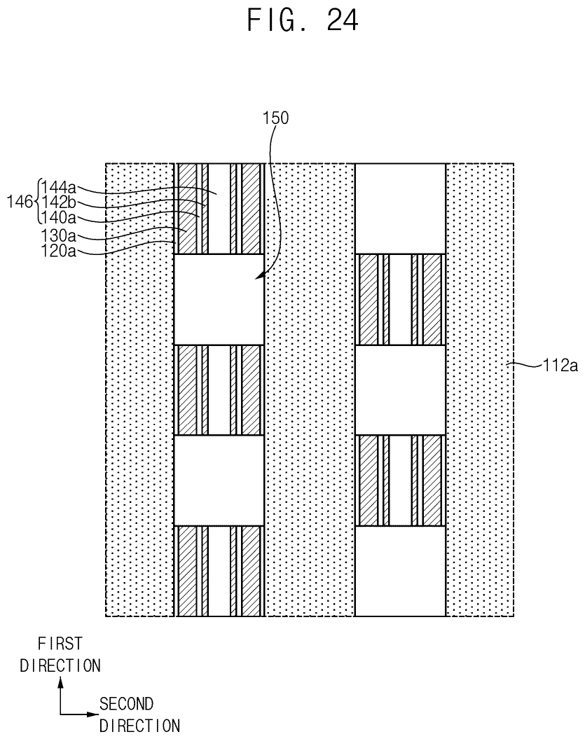

In some example embodiments, as shown in FIG. 24, the first openings 150 disposed in the first trenches 114 adjacent in the second direction are not aligned in the second direction. The first openings may be arranged in a zigzag fashion. The first openings 150 may have an isolated shape. In this case, the first opening 150 may have, e.g., an internal width in the second direction of 2 times the predetermined size and a pitch of 4 times the predetermined size in the second direction.

When the first opening 150 is formed, the preliminary interface insulation pattern 140 and the preliminary channel 142a in the first trench 114 may be cut to form an interface insulation pattern 140a and a channel 142b having a U-shape, respectively. Additionally, the preliminary first filling insulation pattern 144 disposed on the channel 142b may be cut to form the first filling insulation pattern 144a. A preliminary channel structure 146 may include the interface insulation patterns 140a, the channel 142b, and the first filling insulation pattern 144a, and a plurality of the preliminary channel structure 146 may be spaced apart from each other in the first direction in the first trench 114.

Additionally, the preliminary channel structure 146 may have a first sidewall and a second sidewall facing the first sidewall in the second direction. The interface insulation patterns 140a may correspond to the first and second sidewalls of the preliminary channel structure 146, respectively. A ferroelectric structure 130a and a first oxide layer pattern 120a may be formed on the interface insulation patterns 140a corresponding to the first and second sidewalls of the preliminary channel structure 146 by cutting the preliminary ferroelectric structure 130 and the first oxide layer 120. In some example embodiments, the first oxide layer 120 is not cut by forming the first opening 150.

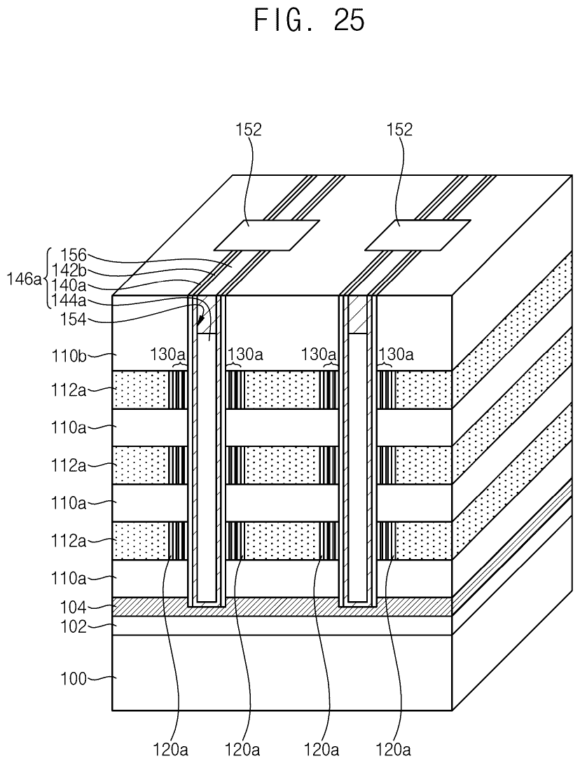

Referring to FIG. 25, a second filling insulation pattern 152 is formed in the first openings 150. The second filling insulation pattern 152 may include, e.g., silicon oxide or silicon nitride. For example, the first openings 150 may be filled with the second filling insulation pattern 152.

An upper portion of the first filling insulation pattern 144a included in the preliminary channel structure 146 may be etched to form a second recess 154. In some example embodiments, upper portions of the channel 142b and the interface insulation patterns 140a may be partially etched together in the etching process.

A conductive layer may be formed on the uppermost insulation pattern 110b, the second filling insulation pattern 152, the channel 142b, and the interface insulation patterns 140a to fill the second recess 154. The conductive layer may be planarized until upper surfaces of the uppermost insulation pattern 110b and the second filling insulation pattern 152 are exposed to form a capping conductive pattern 156 filling the second recess 154. The capping conductive pattern 156 may contact an upper portion of the channel 142b. In example embodiments, the capping conductive pattern 156 may include polysilicon.

The channel 142b, the interface insulation patterns 140a, the first filling insulation pattern 144a, and the capping conductive pattern 156 in the first trench 114 may serve as a channel structure 146a.

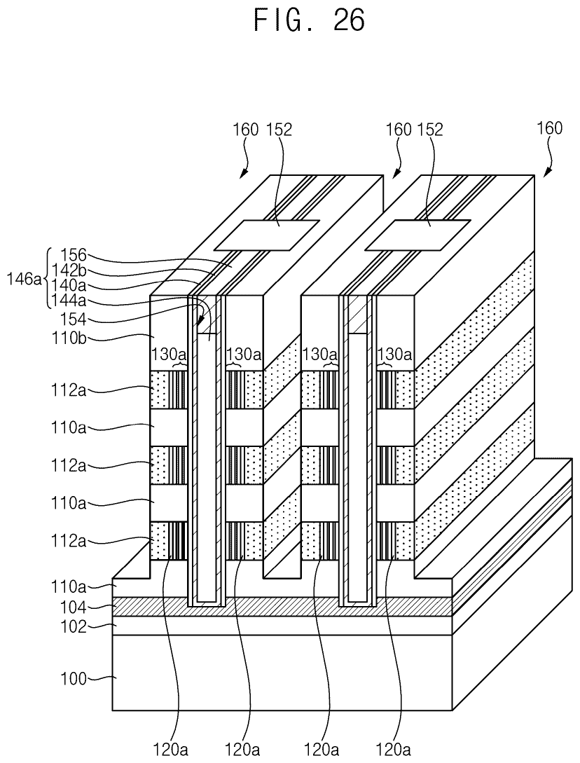

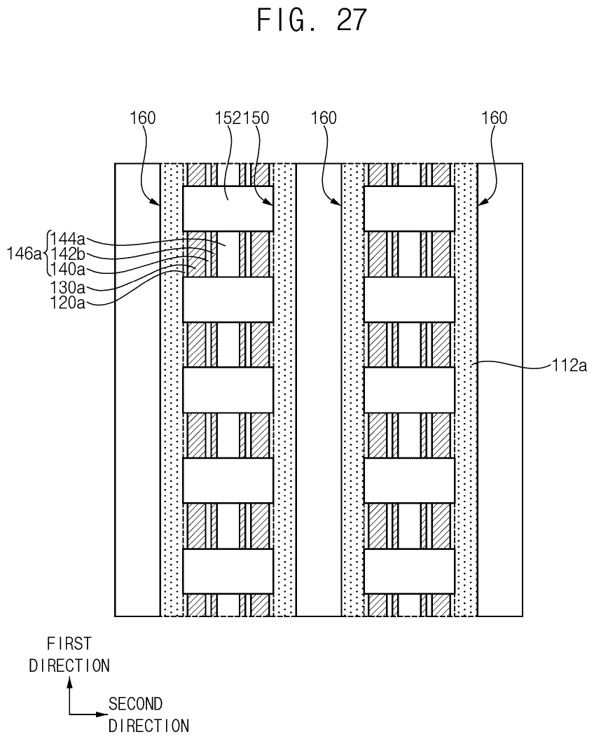

Referring to FIGS. 26 and 27, the sacrificial pattern 112a and the insulation patterns 110a and 110b disposed between the first trenches 114 adjacent in the second direction may be anisotropically etched to form a second trench 160. For example, portions of the sacrificial pattern 112a and the insulation patterns 110a and 110b may be removed to form the second trench 160. The sacrificial pattern 112a and the insulation patterns 110a and 110b may be separated by the second trench 160. In example embodiments, a bottom of the second trench 160 may expose a lowermost insulation pattern 110a.

The second trench 160 may extend in the first direction. The second trench 160 may be parallel to the first trench 114. The second trench 160 may serve as a word line cutting region. The sacrificial pattern 112a and the insulation patterns 110a and 110b may be exposed by the sidewalls of the second trench 160.

In example embodiments, the second trench 160 may be positioned on a central portion between the first trenches 114.

Referring to FIG. 28, the sacrificial pattern 112a corresponding to the sidewall of the second trench 160 may be removed to form a third recess 162. The third recess 162 may be a portion where the sacrificial pattern 112a is removed. The third recess 162 may be communicated with or be part of the second trench 160. The removing process of the sacrificial pattern 112a may include an isotropic etching process, e.g., a wet etching process.

The third recess 162 may extend in the first direction. The first oxide layer pattern 120a may be exposed by the sidewall of the third recess 162, and insulation patterns 110a and 110b may be exposed by upper and lower surfaces of the third recess 162.

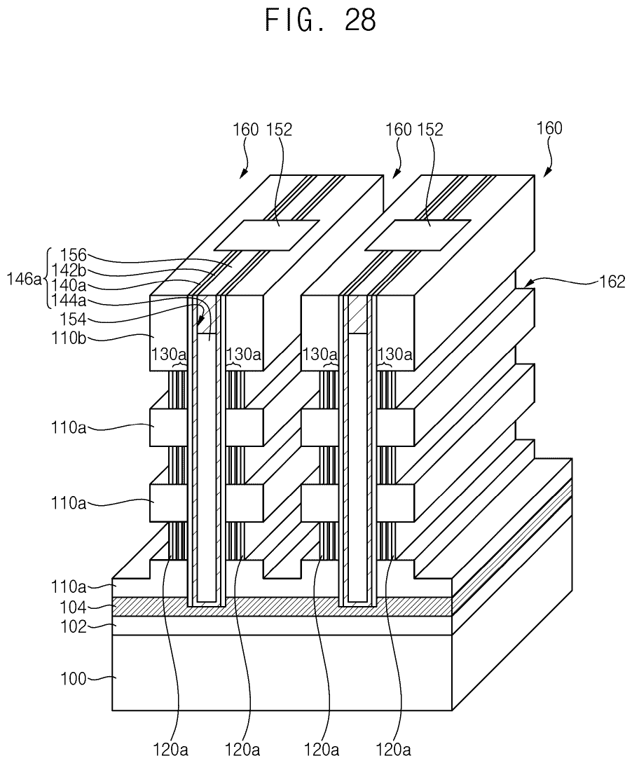

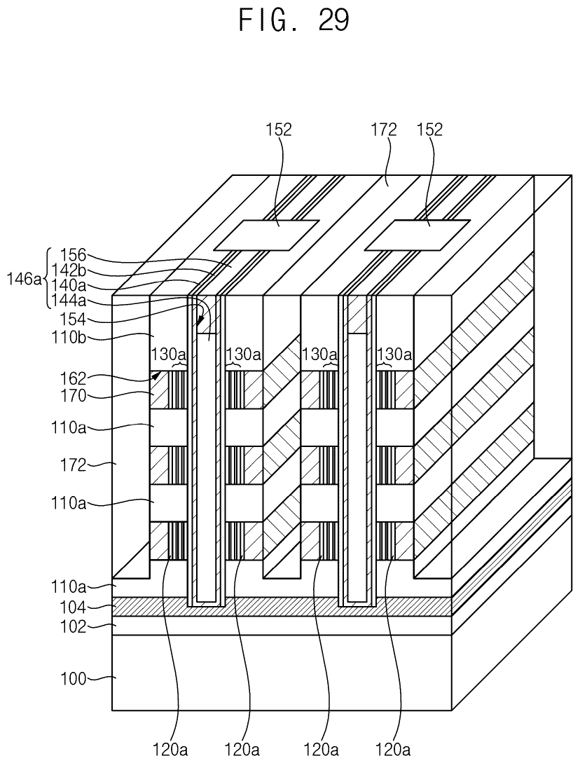

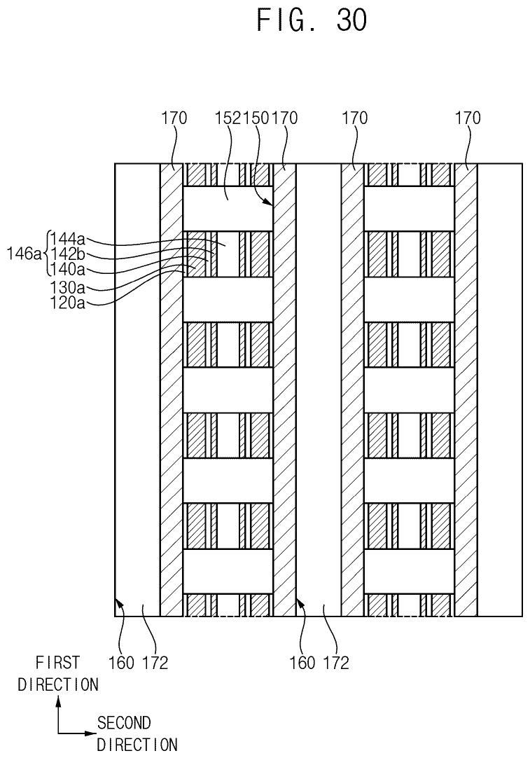

Referring to FIGS. 29 and 30, a conductive layer may be formed on a sidewall and bottom of the second trench 160 and the upper surfaces of the uppermost insulation pattern 110b, the channel structure 146a and the second filling insulation pattern 152. The conductive layer may fill the third recess 162. The conductive layer formed on the sidewalls of the insulation patterns 110a and 110b in the second trench 160 and the bottom of the second trench 160 may be removed, so that the conductive layer remains only in the third recess 162. Accordingly, a conductive pattern 170 may be formed in the third recess 162. The conductive pattern 170 may serve as a gate electrode. Additionally, the conductive pattern 170 extending in the first direction may serve as a word line.

The removing process of the conductive layer may include an isotropic etching process, e.g., a wet etching process.

A third filling insulation pattern 172 may be formed in the second trench 160.

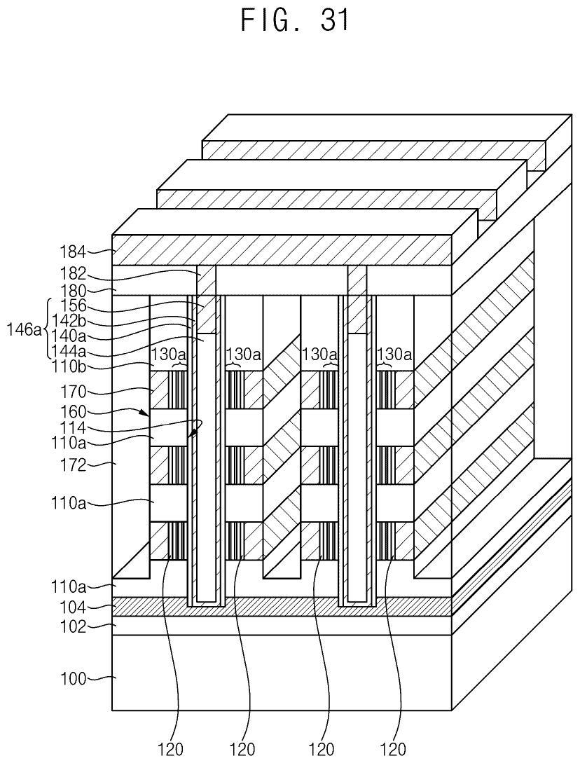

Referring to FIG. 31, a first insulating interlayer 180 may be formed on the uppermost insulation pattern 110b, the channel structure 146a, the second filling insulation pattern 152, and the third filling insulation pattern 172. A contact plug 182 may be formed through the first insulating interlayer 180, and the contact plug 182 may contact the capping conductive pattern 156. Additionally, an upper conductive line 184 extending in the second direction may be formed on the contact plug 182. The upper conductive line 184 may serve as a bit line structure.

A vertical semiconductor device may be manufactured by the above described processes.

Hereinafter, semiconductor devices having various stacked structures of patterns serving as memory cells may be presented.

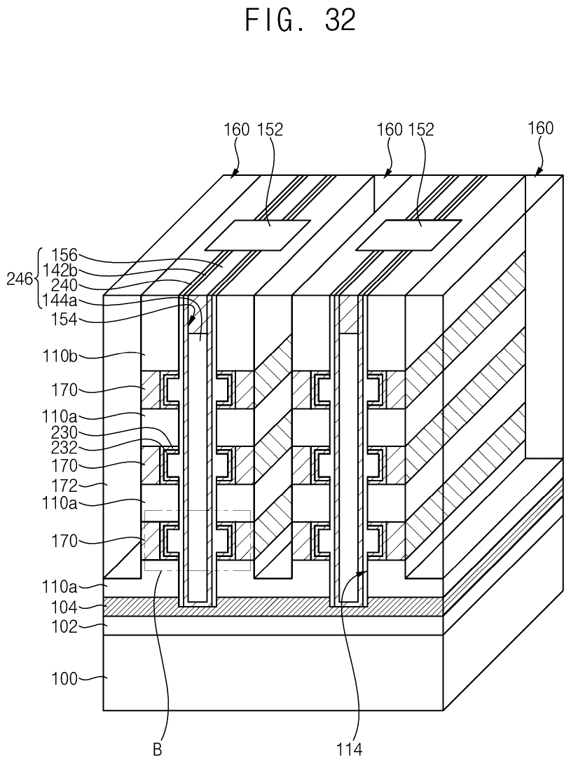

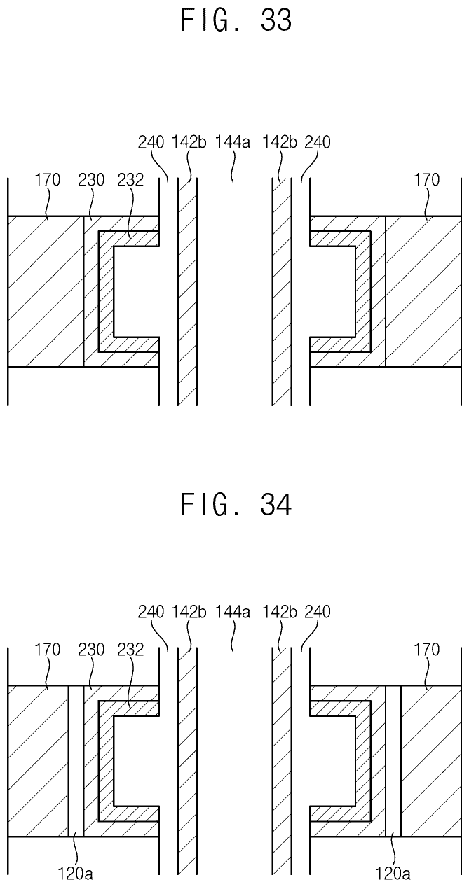

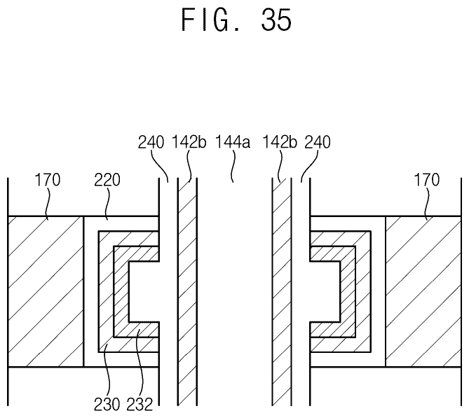

FIG. 32 is a perspective view illustrating a vertical semiconductor device in accordance with an example embodiment of the present inventive concept. FIG. 33 is an enlarged cross-sectional view of a memory cell of a vertical semiconductor device in accordance with an example embodiment of the present inventive concept. FIG. 34 is an enlarged cross-sectional view of a memory cell of a vertical semiconductor device in accordance with an example embodiment of the present inventive concept. FIG. 35 is an enlarged cross-sectional view of a memory cell of a vertical semiconductor device in accordance with an example embodiment of the present inventive concept.

FIG. 33 is an enlarged cross-sectional view of portion B of FIG. 32.

The vertical semiconductor device may be the same as the vertical semiconductor device described with reference to FIG. 1, except for the memory cell. In FIG. 32, the first insulating interlayer, the contact plug, and the conductive line are omitted to avoid complication of the drawing.

Referring to FIGS. 32 and 33, the lower insulating interlayer 102 and the common source plate 104 may be formed on the substrate 100, as described with reference to FIG. 1. The insulation patterns 110a and 110b may be formed on the common source plate 104. The first trench 114 may pass through the insulation patterns 110a and 110b.

Channel structures 246 may be formed in the first trench 114. The channel structures 246 may include a channel 142b, an interface insulation pattern 240, a first filling insulation pattern 144a, and a capping conductive pattern 156. The second filling insulation pattern 152 may be disposed in the first trench 114, and may be disposed between the channel structures 246 spaced apart from each other in the first direction.

A recess may be defined as neighboring insulation patterns 110a and 110b in the vertical direction and the channel structure 246. The recess may extend in the first direction.

The conductive pattern 170 may be formed in the recess, and may be spaced apart from the interface insulation pattern 240. The conductive pattern 170 may extend in the first direction.

In an embodiment, in the recess, a ferroelectric liner 230 and a floating gate electrode 232 are disposed between the interface insulation pattern 240 and the conductive pattern 170.

The ferroelectric liner 230 may be conformally formed on the neighboring insulation patterns 110a and 110b in the vertical direction and the sidewalls of the conductive pattern 170 in the recess. The ferroelectric liner 230 may have a “⊏” shape.

In example embodiments, the ferroelectric liner 230 may include a ferroelectric material.

The floating gate electrode 232 may be formed conformally on the surface of the ferroelectric liner 230. The floating gate electrode 232 may have a “⊏” shape.

In an embodiment, the ferroelectric liner 230 and the floating gate electrode 232 are only disposed in the recess, and are not disposed on the surfaces of the insulation patterns 110a and 110b in the first trench 114.

In example embodiments, the floating gate electrode 232 may include polysilicon.

A plurality of interface insulation patterns 240 may be formed on both sidewalls facing each other in the second direction of the first trench 114, respectively. The interface insulation pattern 240 may be formed on the floating gate electrode 232 to fill the recess. The interface insulation pattern 240 may include a portion extending in the vertical direction and a portion protruding toward the recess. The interface insulation pattern 240 may contact the surface of the floating gate electrode 232, and may also contact an end of the ferroelectric liner 230.

In some example embodiments, as shown in FIG. 34, the first oxide layer pattern 120a may be disposed between the conductive pattern 170 and the ferroelectric liner 230. In an embodiment, the first oxide layer pattern 120a directly contacts the sidewall of the conductive pattern 170, and is not formed on the surfaces of the neighboring insulation patterns 110a and 110b in the vertical direction. The first oxide layer pattern 120a may have a vertically standing shape.

In some example embodiments, as shown in FIG. 35, the first oxide layer pattern 220 is disposed between the conductive pattern 170 and the ferroelectric liner 230. The first oxide layer pattern 220 may be conformally formed on the surfaces of the neighboring insulation patterns 110a and 110b in the vertical direction and the surface of the conductive pattern 170 in the recess. That is, the first oxide layer pattern 220 may be formed to have a “⊏”-shaped cross section. The ferroelectric liner 230 and the floating gate electrode 232 may be disposed on the first oxide layer pattern 220.

The interface insulation pattern 240, the floating gate electrode 232, the ferroelectric liner 230, and the conductive pattern 170 stacked on the first and second sidewalls of the channel 142b may serve as a unit memory cell. The ferroelectric liner 230 and the floating gate electrode 232 may be conformally formed along a surface of the recess.

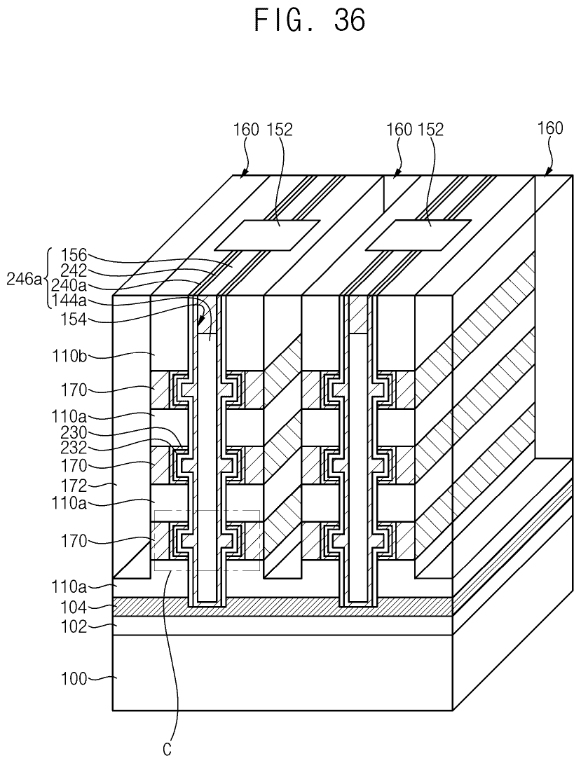

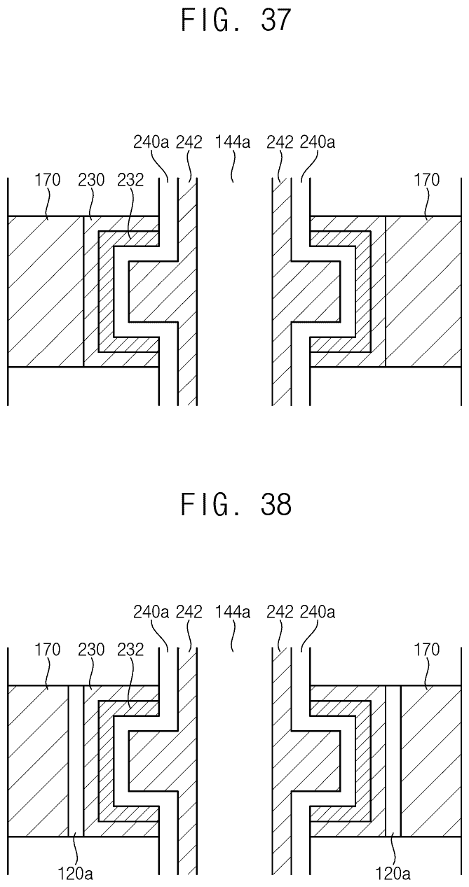

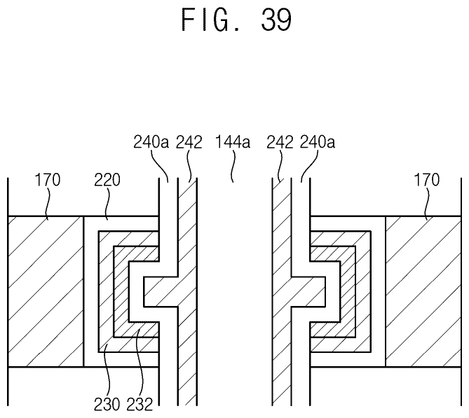

FIG. 36 is a perspective view illustrating a vertical semiconductor device in accordance with an example embodiment of the present inventive concept. FIG. 37 is an enlarged cross-sectional view of a memory cell of a vertical semiconductor device in accordance with an example embodiment of the present inventive concept. FIG. 38 is an enlarged cross-sectional view of a memory cell of a vertical semiconductor device in accordance with an example embodiment of the present inventive concept. FIG. 39 is an enlarged cross-sectional view of a memory cell of a vertical semiconductor device in accordance with an example embodiment of the present inventive concept.

FIG. 37 is an enlarged cross-sectional view of portion C in FIG. 36. In FIG. 36, the first insulating interlayer, the contact plug and the conductive line are omitted to avoid complication of the drawing.

The vertical semiconductor device may be the same as the vertical semiconductor device described with reference to FIG. 1, except for the memory cell.

Referring to FIGS. 36 and 37, the lower insulating interlayer 102 and the common source plate 104 may be disposed on the substrate 100, as described with reference to FIGS. 32 and 33. The insulation patterns 110a and 110b may be disposed on the common source plate 104, and the first trench 114 extending in the first direction may be formed through the insulation patterns 110a and 110b.

The channel structures 246a may be disposed in the first trench 114. Each of the channel structures 246a may include the channel 242, the interface insulation pattern 240a, the first filling insulation pattern 144a, and the capping conductive pattern 156. The second filling insulation pattern 152 may be disposed in the first trench 114, and may be disposed between the channel structures 246a being spaced apart from each other in the first direction.

A recess may be defined by the neighboring insulation patterns 110a and 110b in the vertical direction and the channel structure 246a. The recess may extend in the first direction.

The conductive pattern 170 may be in the recess, and the conductive pattern 170 may be spaced apart from the interface insulation pattern 240a. The conductive pattern 170 may extend in the first direction.

In the recess, a ferroelectric liner 230 and a floating gate electrode 232 may be disposed between the interface insulation pattern 240a and the conductive pattern 170.

The ferroelectric liner 230 may be conformally formed on the neighboring insulation patterns 110a and 110b and the sidewall of the conductive pattern 170 in the recess. The ferroelectric liner 230 may have a “⊏” shape.

The floating gate electrode 232 may be formed conformally on the surface of the ferroelectric liner 230. The floating gate electrode 232 may have a “⊏” shape.

In an embodiment, the ferroelectric liner 230 and the floating gate electrode 232 are disposed only in the recess, and are not disposed on the surfaces of the insulation patterns 110a and 110b in the first trench 114.

The interface insulation patterns 240a may be formed on both sidewalls facing each other in the second direction of the first trench 114, respectively. The interface insulation pattern 240a may be formed conformally on the surface of the floating gate electrode 232. The interface insulation pattern 240a may include a portion extending in the vertical direction and a portion protruding toward the recess. The interface insulation pattern 240a may contact the surface of the floating gate electrode 232, and may also contact an end of the ferroelectric liner 230.

The channel 242 may be formed on an upper surface of the interface insulation pattern 240a and the surface of the common source plate 104. The channel 242 may be formed on the interface insulation pattern 240a to fill the recess. The channel 242 may be formed conformally on the surface of the interface insulation pattern 240a. The interface insulation pattern 240a may include a portion extending in the vertical direction, a portion laterally protruding toward the recess, and a portion contacting the common source plate 104. The interface insulation pattern 240a may contact the surface of the floating gate electrode 232, and may also contact an end of the ferroelectric liner 230.

The interface insulation pattern 240a, the floating gate electrode 232, the ferroelectric liner 230, and the conductive pattern 170 stacked on the first and second sidewalls of the channel 242 may serve as a unit memory cell. The ferroelectric liner 230 and the floating gate electrode 232 may be conformally formed along a surface of the recess.

In some example embodiments, as shown in FIG. 38, the first oxide layer pattern 120a is disposed between the conductive pattern 170 and the ferroelectric liner 230. In an embodiment, the first oxide layer pattern 120a contacts the sidewall of the conductive pattern 170, and is not formed on the surfaces of the neighboring insulation patterns 110a and 110b in the vertical direction. The first oxide layer pattern 120a may have a vertically standing shape. The first oxide layer 120a may directly contact the sidewall of the conductive pattern 170.

In some example embodiments, as shown in FIG. 39, the first oxide layer pattern 220 may contact the surfaces of the neighboring insulation patterns 110a and 110b in the vertical direction and the surface of the conductive pattern 170 in the recess. The first oxide layer pattern 220 may be formed to have a “⊏” shape, in a cross sectional view. The ferroelectric liner 230 and the floating gate electrode 232 may be disposed on the first oxide layer pattern 220.

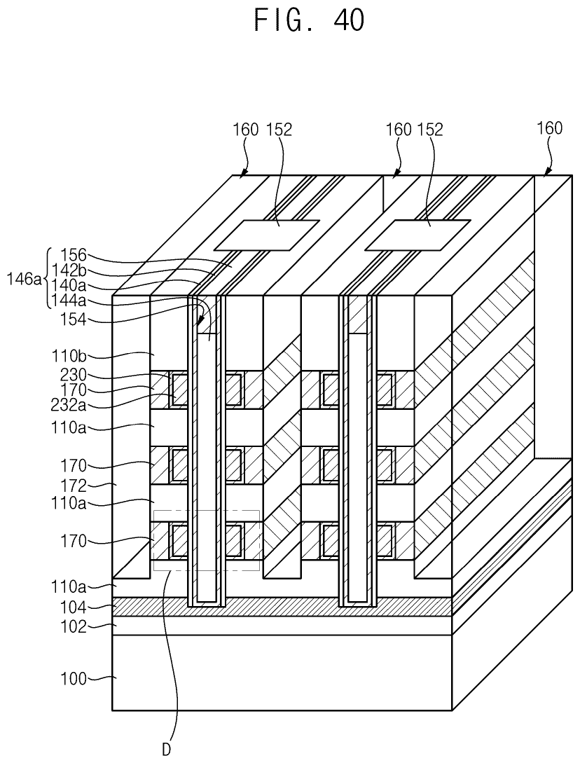

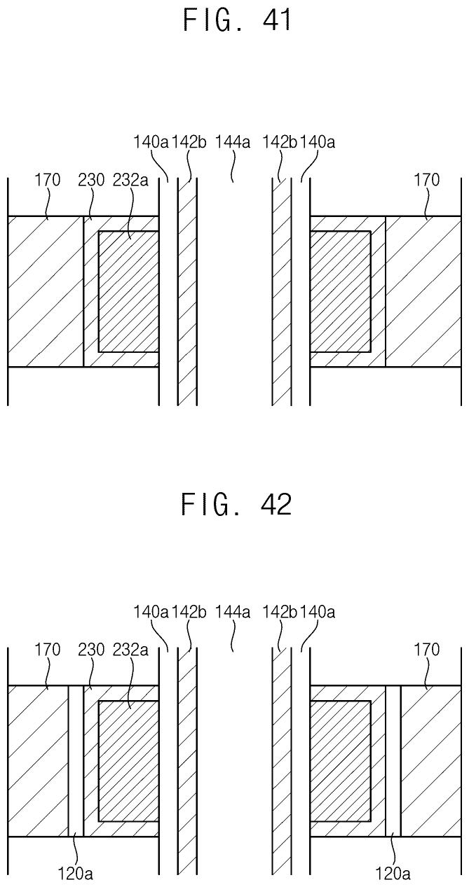

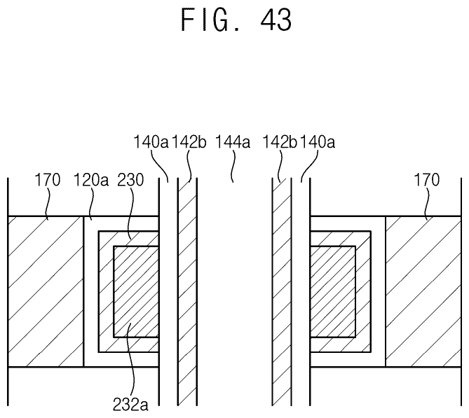

FIG. 40 is a perspective view illustrating a vertical semiconductor device in accordance with an example embodiment of the present inventive concept. FIG. 41 is an enlarged cross-sectional view of a memory cell of a vertical semiconductor device in accordance with an example embodiment of the present inventive concept. FIG. 42 is an enlarged cross-sectional view of a memory cell of a vertical semiconductor device in accordance with an example embodiment of the present inventive concept. FIG. 43 is an enlarged cross-sectional view of a memory cell of a vertical semiconductor device in accordance with an example embodiment of the present inventive concept. In FIG. 40, the first insulating interlayer, the contact plug, and the conductive line are omitted to avoid complication of the drawing.

FIG. 41 is an enlarged cross-sectional view of portion D in FIG. 40.

Referring to FIGS. 40 and 41, the lower insulating interlayer 102 and the common source plate 104 are disposed on the substrate 100. The insulation patterns 110a and 110b may be disposed on the common source plate 104. The first trench 114 extending in the first direction may pass through the insulation patterns 110a and 110b. The channel structures 146a may be disposed in the first trench 114. The channel structure 146a may include the channel 142b, the interface insulation patterns 140a, the first filling insulation pattern 144a, and the capping conductive pattern 156. A second filling insulation pattern 152 may be disposed in the first trench 114, and the second filling insulation pattern 152 may be disposed between the channel structures 146a that are spaced apart from each other in the first direction.

A recess may be defined by neighboring insulation patterns 110a and 110b in the vertical direction and the channel structure 246. The recess may extend in the first direction.

The conductive pattern 170 may be formed in the recess, and may be spaced apart from the interface insulation pattern 140a. The conductive pattern 170 may extend in the first direction.

In the recess, the ferroelectric liner 230 and the floating gate electrode 232a may be disposed between the interface insulation pattern 140a and the conductive pattern 170.

The ferroelectric liner 230 may be conformally formed on the neighboring insulation patterns 110a and 110b in the vertical direction and the sidewalls of the conductive pattern 170 in the recess. The ferroelectric liner 230 may have a “ [symbol] ” shape.

The floating gate electrode 232a may contact the ferroelectric liner 230, and may fill or mostly fill a space between the interface insulation pattern 140a and the conductive pattern 170 in the recess. The ferroelectric liner 230 may surround upper and lower surfaces and a sidewall of the floating gate electrode 232a.

A surface of the floating gate electrode 232a and an end of the ferroelectric liner 230 may be covered the interface insulation pattern 140a.

The interface insulation patterns 140a may be formed on both sidewalls facing each other in the second direction of the first trench 114, respectively. The channel 142b may be conformally formed on the surface of the interface insulation pattern 140a and the upper surface of the common source plate 104. The channel 142b may have a U-shape. The first filling insulation pattern 144a may be formed on the inner surface of the channel 142b to fill or mostly fill the first trench 114. The capping conductive pattern 156 may be disposed on the first filling insulation pattern 144a, and may contact the channel 142b.

The vertical semiconductor devices in accordance with an example embodiment of the present inventive concept may be used as memories included in electronic products such as mobile devices, memory cards, and computers.

While the present inventive concept has been described with reference to example embodiments thereof, it will be understood by those of ordinary skill in the art that various changes in form and details may be made thereto without departing from the spirit and scope of the present inventive concept.

What is claimed is:

1. A vertical semiconductor device comprising:
a plurality of insulation patterns disposed on a substrate, wherein the plurality of insulation patterns are spaced apart from each other in a vertical direction;
a plurality of channel structures spaced apart from each other in a first direction, each of the plurality of channel structures including interface insulation patterns, and the plurality of channel structures are disposed in a first trench extending in the first direction and passing through the insulation patterns in the vertical direction;
a ferroelectric structure disposed on an outer surface of each of the plurality channel structures, the ferroelectric structure protruding in a direction towards a gap between some of the insulation patterns in the vertical direction; and
a conductive pattern disposed on a sidewall of the ferroelectric structure, the conductive pattern filling the gap in the vertical direction.

2. The vertical semiconductor device of claim 1, wherein the interface insulation patterns are formed on first and second sidewalls facing each other of the first trench, respectively, and a channel having a U-shape is located on the interface insulation patterns and the substrate.

3. The vertical semiconductor device of claim 2, wherein the channel structure further includes a first filling insulation pattern disposed on the channel to fill the first trench, and a capping conductive pattern disposed on the first filling insulation pattern to contact an upper portion of the channel.

4. The vertical semiconductor device of claim 1, wherein the ferroelectric structure comprises ferroelectric layers and conductive material layers that are alternately stacked.

5. The vertical semiconductor device of claim 4, wherein at least one of the ferroelectric layers includes a hafnium oxide layer, a zirconium oxide layer, or a hafnium zirconium oxide layer, and the ferroelectric layer has an orthorhombic phase.

6. The vertical semiconductor device of claim 4, wherein at least one of the conductive material layers includes titanium, titanium oxide, or a metallic two-dimensional material.

7. The vertical semiconductor device of claim 4, wherein the ferroelectric layers and the conductive material layers are stacked on each of the interface insulation patterns, and the ferroelectric layers and the conductive material layers have a vertically standing shape.

8. The vertical semiconductor device of claim 1, further comprising an oxide layer pattern disposed between the ferroelectric structure and the conductive pattern, wherein the oxide layer pattern contacts the conductive pattern.

9. The vertical semiconductor device of claim 1, further comprising a floating gate electrode disposed between one of the interface insulation patterns and the ferroelectric structure.

10. The vertical semiconductor device of claim 1, wherein the ferroelectric structure is disposed on first and second sidewalls facing each other in a second direction perpendicular to the first direction of a corresponding one of the channel structures.

11. The vertical semiconductor device of claim 1, wherein the conductive pattern extends in the first direction, and the conductive pattern faces the plurality of channel structures arranged in the first direction.

12. The vertical semiconductor device of claim 1, further comprising an upper conductive line disposed on a corresponding one of the channel structures, and the upper conductive line extends in a second direction perpendicular to the first direction.

13. The vertical semiconductor device of claim 1, wherein a plurality of first trenches are spaced apart in a second direction perpendicular to the first direction, further comprising:
a second trench extending in the first direction between the first trenches, and
a second filling insulation pattern disposed in the second trench, the second filling insulation pattern extending in the first direction and contacting sidewalls of a corresponding one of the conductive patterns and a corresponding one of the insulation patterns in the second trench.

14. A vertical semiconductor device comprising:
a lower insulating interlayer and a common source plate sequentially stacked on a substrate;
a plurality of insulation patterns disposed on the common source plate, and spaced apart from each other in a vertical direction;
a plurality channel structures disposed in a first trench and spaced apart from each other in a first direction, each of the plurality channel structures including interface insulation patterns disposed on each of first and second sidewalls of the first trench, and a channel disposed on the interface insulation patterns and the common source plate;
a ferroelectric structure disposed on a surface of each of the interface insulation pattern, the ferroelectric structure protruding toward a gap between some of the insulation patterns in the vertical direction; and
a conductive pattern disposed on a sidewall of the ferroelectric structure, the conductive pattern filling the gap,
wherein a plurality of first trenches extend in the first direction and are arranged in a second direction different from the first direction, and the plurality of first trenches pass through the insulation patterns in the vertical direction.

15. The vertical semiconductor device of claim 14, further comprising:
a second trench extending in the first direction disposed between the first trenches; and
a second filling insulation pattern disposed in the second trench, the second filling insulation pattern extending in the first direction and contacting sidewalls of the conductive patterns and insulation patterns in the second trench.

16. The vertical semiconductor device of claim 14, wherein each of the first trenches has an internal width of a predetermined size, and a sum of the internal width of the first trench and a space between the first trenches is four times the predetermined size.

17. The vertical semiconductor device of claim 14, wherein each of the channel structures disposed in the first trenches adjacent in the second direction are disposed to be aligned in the second direction.

18. A vertical semiconductor device comprising:
a channel disposed on a substrate, the channel including a first vertical extension, a horizontal extension, and a second vertical extension, and having a U-shape;
interface insulation patterns disposed on an outer surface of the first vertical extension of the channel and the outer surface of the second vertical extension of the channel, respectively;
ferroelectric structures stacked on a surface of each of the interface insulation pattern, wherein the ferroelectric structures are spaced apart from each other in a vertical direction; and
conductive patterns disposed on a sidewall of each of the ferroelectric structures.

19. The vertical semiconductor device of claim 18, wherein the ferroelectric structure comprises ferroelectric layers and conductive material layers that are alternately stacked, and the ferroelectric layers and conductive material layers have a vertically standing shape.

20. The vertical semiconductor device of claim 18, wherein the interface insulation patterns, the ferroelectric structures and the conductive patterns stacked on an outer surface of the first vertical extension of the channel serve as a first memory cell, and
the interface insulation patterns, the ferroelectric structures and the conductive patterns stacked on an outer surface of the second vertical extension of the channel serve as a second memory cell distinct from the first metal cell.
